(19) United States
(12) Patent Application Publication
(10) Pub. No.: US 2025/0143140 A1
(43) Pub. Date: May 1, 2025

(54) DISPLAY DEVICE AND METHOD FOR MANUFACTURING THE SAME

(71) Applicant: Samsung Display Co., LTD., Yongin-si (KR)

(72) Inventors: Nam Jin KIM, Yongin-si (KR); Yeon Ju SEO, Yongin-si (KR); Ki Hoon KIM, Yongin-si (KR)

(21) Appl. No.: 18/677,307

(22) Filed: May 29, 2024

(30) Foreign Application Priority Data
Oct. 30, 2023 (KR) 10-2023-0146784

(51) Int. Cl. H10K 59/80; H10K 59/12; H10K 59/122; H10K 59/40; H10K 71/60

(52) U.S. Cl. CPC H10K 59/873; H10K 59/1201; H10K 59/122; H10K 59/40; H10K 71/60

(57) ABSTRACT

A display device includes: a substrate comprising a display area in which emission areas are arranged and a non-display area around the display area; a circuit layer on the substrate; and an element layer on the circuit layer, wherein the non-display area includes: a dam area where at least one dam portion surrounding the display area is arranged and spaced apart from the display area; and a junction area between an edge of the substrate and the dam area, wherein the circuit layer includes: a barrier layer on the substrate; a buffer layer on the barrier layer; and two or more inorganic insulating layers on the buffer layer and containing an inorganic insulating material, the display device further comprising a groove in a part of the junction area, spaced apart from the dam area and the edge of the substrate, and penetrating the barrier layer and the buffer layer.

### CROSS-REFERENCE TO RELATED APPLICATION

The present application claims priority to and the benefit of Korean Patent Application No. 10-2023-0146784, filed on Oct. 30, 2023, in the Korean Intellectual Property Office, the entire disclosure of which is incorporated herein by reference.

### BACKGROUND

### 1. Field

Aspects of some embodiments of the present disclosure relate to a display device and a method for manufacturing the same.

### 2. Description of the Related Art

With the advance of information-oriented society, more and more demand may be placed on display devices for displaying images in various ways. For example, display devices are employed in various electronic devices such as smartphones, digital cameras, laptop computers, navigation devices, and smart televisions.

A display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

An organic light emitting display device may generally display images using light emitting elements, each including a light emitting layer made of an organic light emitting material. As described above, the organic light emitting display device implements image display using a self-light emitting element, and thus may have relatively superior performance in power consumption, response speed, luminous efficiency, luminance, and wide viewing angle compared to other display devices.

One surface of the display device may include a display area at which images are displayed and a non-display area that is a periphery of the display area. Emission areas emitting light with respective luminances and colors may be arranged in the display area.

That is, the display device may include a substrate including a display area and a non-display area, a circuit layer including pixel drivers on the substrate and respectively corresponding to the emission areas, an element layer including light emitting elements on the circuit layer and respectively corresponding to the emission areas, and an encapsulation layer on the element layer.

The encapsulation layer may include a first encapsulation layer bonded to the inorganic insulating material of the circuit layer in the non-display area. Permeation of oxygen or moisture or other contaminants may be blocked by such an encapsulation layer, and rapid deterioration of the organic light emitting material and the like of the element layer may be prevented or relatively reduced.

The above information disclosed in this Background section is only for enhancement of understanding of the background and therefore the information discussed in this Background section does not necessarily constitute prior art.

### SUMMARY

According to some embodiments, an encapsulation layer may include the first encapsulation layer covering the element layer, a second encapsulation layer including an organic insulating material, and a third encapsulation layer covering the second encapsulation layer. According to some embodiments, each of the first encapsulation layer and the third encapsulation layer may include an inorganic insulating material.

According to some embodiments, the non-display area of the substrate may include a dam area where at least one dam portion surrounding the display area is arranged, and a junction area between the dam area and the edge of the substrate.

According to some embodiments, inorganic insulating materials that are sequentially stacked may be in the junction area. That is, a junction structure between the inorganic insulating materials may be provided in the junction area. Accordingly, the generation of an oxygen or moisture permeation path from the edge of the substrate toward the display area may be relatively reduced or delayed.

To this end, the second encapsulation layer may be limitedly located in the area surrounded by at least one dam portion.

However, in the process of forming the second encapsulation layer, if an organic insulating material whose amount is greater than the amount of an organic insulating material that fills the area surrounded by at least one dam portion is dropped, the organic insulating material may overflow to the junction area around the at least one dam portion.

Further, as the width of the non-display area decreases in order to reduce the ratio of the non-display area in the display surface of the display device, the width of the junction area may also decrease. In this case, the organic insulating material overflowing to the junction area may spread to the edge of the substrate.

Hence, lifting defects of the inorganic insulating materials stacked in the junction area may easily occur. In addition, the oxygen or moisture permeation path from the edge of the substrate toward the display area may be generated through the gap between the inorganic insulating materials.

In view of the above, aspects of the present disclosure include a display device capable of preventing or reducing lifting defects caused by an organic insulating material overflowing to a junction area, and a method for manufacturing the same.

According to some embodiments of the present disclosure, a display device comprises a substrate includes: a display area in which emission areas are arranged and a non-display area around the display area; a circuit layer on the substrate; and an element layer on the circuit layer. According to some embodiments, the non-display area comprises a dam area where at least one dam portion surrounding the display area is arranged and spaced apart from the display area; and a junction area between an edge of the substrate and the dam area. According to some embodiments, the circuit layer comprises a barrier layer on the substrate; a buffer layer on the barrier layer; and two or more inorganic insulating layers on the buffer layer and containing an inorganic insulating material. According to some embodiments, the display device further comprising a groove in a part of the junction area, spaced apart from the dam area and the edge of the substrate, and penetrating the barrier layer and the buffer layer.

According to some embodiments, the two or more inorganic insulating layers extend to a first boundary area in contact with the dam area in the junction area. According to some embodiments, a first crack dam is provided by side surfaces of the two or more inorganic insulating layers. According to some embodiments, the first crack dam is spaced apart from the groove.

According to some embodiments, the display device further comprises an encapsulation layer on the element layer; and a touch sensor layer on the encapsulation layer. According to some embodiments, the encapsulation layer comprises a first encapsulation layer on the element layer and containing an inorganic insulating material; a second encapsulation layer in the display area on the first encapsulation layer and containing an organic insulating material; and a third encapsulation layer on the first encapsulation layer, covering the second encapsulation layer, and containing an inorganic insulating material. According to some embodiments, the touch sensor layer comprises a touch buffer layer on the third encapsulation layer and containing an inorganic insulating material; and a touch interlayer insulating layer on the touch buffer layer and containing an inorganic insulating material. According to some embodiments, the first encapsulation layer extends to the edge of the substrate, and covers the at least one dam portion and the groove. According to some embodiments, the second encapsulation layer is in an area surrounded by the at least one dam portion. According to some embodiments, the touch interlayer insulating layer extends to a third boundary area which is the remaining area excluding the second boundary area in contact with the edge of the substrate in the junction area. According to some embodiments, a second crack dam comprising a side surface of the touch interlayer insulating layer is provided.

According to some embodiments, the second crack dam is between the edge of the substrate and the groove. According to some embodiments, the touch interlayer insulating layer overlaps the groove.

According to some embodiments, the second crack dam is between the groove and the first crack dam.

According to some embodiments, at least a part of the touch buffer layer or at least a part of the third encapsulation layer extends to the third boundary area. According to some embodiments, the second crack dam further comprises a side surface of the touch buffer layer or a side surface of the third encapsulation layer.

According to some embodiments, some of the organic insulating material of the second encapsulation layer which overflows to the junction area spreads to a part of the junction area between the dam area and the groove, and is accommodated on a part of the first encapsulation layer which overlaps the groove.

According to some embodiments, the substrate comprises a main region comprising the display area and the non-display area, and a sub-region protruding from one side of the main region. According to some embodiments, the groove faces the other sides except one side connected to the sub-region in the edge of the main region.

According to some embodiments, the two or more inorganic insulating layers comprise a first gate insulating layer covering a first semiconductor layer on the buffer layer; a second gate insulating layer covering a first gate conductive layer on the first gate insulating layer; a first interlayer insulating layer covering a second gate conductive layer on the second gate insulating layer; a third gate insulating layer covering a second semiconductor layer on the first interlayer insulating layer; and a second interlayer insulating layer covering a third gate conductive layer on the third gate insulating layer.

According to some embodiments, the circuit layer further comprises one or more planarization layers on the second interlayer insulating layer and containing an organic insulating material. According to some embodiments, the element layer comprises anode electrodes respectively in the emission areas; a pixel defining layer in a non-emission area between the emission areas, and covering an edge of each of the anode electrodes; a spacer layer on a part of the pixel defining layer; light emitting layers respectively on the anode electrodes; and a cathode electrode on the pixel defining layer, the spacer layer, and the light emitting layers. According to some embodiments, each of the at least one dam portion comprises two or more dam layers which are sequentially stacked. According to some embodiments, each of the two or more dam layers is the same layer as one of the one or more planarization layers, the pixel defining layer, and the spacer layer.

According to some embodiments of the present disclosure, a method for manufacturing a display device, the method comprises providing a substrate comprising a display area in which emission areas are arranged and a non-display area around the display area; and forming a circuit layer on the substrate. According to some embodiments, the non-display area comprises a dam area spaced apart from the display area and surrounding the display area; and a junction area between an edge of the substrate and the dam area. According to some embodiments, forming the circuit layer comprises forming a barrier layer by stacking an inorganic insulating material on the substrate; forming a buffer layer by stacking an inorganic insulating material on the barrier layer; and forming a groove by partially removing the barrier layer and the buffer layer. According to some embodiments, the groove is in a part of the junction area, and is spaced apart from the dam area and the edge of the substrate.

According to some embodiments, the junction area further comprises a first boundary area in contact with the dam area, and a second boundary area in contact with the edge of the substrate. According to some embodiments, forming the circuit layer further comprises before the forming the groove, forming a first semiconductor layer on the buffer layer; forming a first gate insulating layer covering the first semiconductor layer by stacking an inorganic insulating material on the buffer layer; forming a first gate conductive layer on the first gate insulating layer; forming a second gate insulating layer covering the first gate conductive layer by stacking an inorganic insulating material on the first gate insulating layer; forming a second gate conductive layer on the second gate insulating layer; forming a first interlayer insulating layer covering the second gate conductive layer by stacking an inorganic insulating material on the second gate insulating layer; forming a second semiconductor layer on the first interlayer insulating layer; forming a third gate insulating layer covering the second semiconductor layer by stacking an inorganic insulating material on the first interlayer insulating layer; forming a third gate conductive layer on the third gate insulating layer; forming a second interlayer insulating layer covering the third gate conductive layer by stacking an inorganic insulating material on the third gate insulating layer; and forming a first crack dam comprising side surfaces of the second interlayer insulating layer, the third gate insulating layer, the first interlayer insulating layer, the second gate insulating layer, and the first gate insulating layer by partially removing the second interlayer insulating layer, the third gate insulating layer, the first interlayer insulating layer, the second gate insulating layer, and the first gate insulating layer. According to some embodiments, after forming the first crack dam, the second interlayer insulating layer, the third gate insulating layer, the first interlayer insulating layer, the second gate insulating layer, and the first gate insulating layer extend to the first boundary area. According to some embodiments, the first crack dam is spaced apart from the groove.

According to some embodiments, the method further comprises after forming the circuit layer, forming an element layer on the circuit layer; forming an encapsulation layer on the element layer; and forming a touch sensor layer on the encapsulation layer. According to some embodiments, forming the encapsulation layer comprises forming a first encapsulation layer containing an inorganic insulating material on the element layer; forming a second encapsulation layer containing an organic insulating material on the first encapsulation layer; and forming, on the first encapsulation layer, a third encapsulation layer covering the second encapsulation layer and containing an inorganic insulating material. According to some embodiments, forming the touch sensor layer comprises forming a touch buffer layer by stacking an inorganic insulating material on the third encapsulation layer; forming a first touch conductive layer on the touch buffer layer; forming a touch interlayer insulating layer covering the first touch conductive layer by stacking an inorganic insulating material on the touch buffer layer; forming a second crack dam comprising a side surface of the touch interlayer insulating layer by partially removing the touch interlayer insulating layer; forming a second touch conductive layer on the touch interlayer insulating layer; and forming a touch planarization layer covering the second touch conductive layer by stacking an organic insulating material on the touch interlayer insulating layer. According to some embodiments, after forming the second crack dam, the touch interlayer insulating layer extends to a third boundary area which is the remaining area excluding the second boundary area in the junction area.

According to some embodiments, the second crack dam is between the edge of the substrate and the groove. The touch interlayer insulating layer overlaps the groove.

According to some embodiments, the second crack dam is between the groove and the first crack dam.

According to some embodiments, in forming the second crack dam, the touch buffer layer or the third encapsulation layer is partially removed. According to some embodiments, at least a part of the touch buffer layer or at least a part of the third encapsulation layer extends to the third boundary area. According to some embodiments, the second crack dam further comprises a side surface of the touch buffer layer or a side surface of the third encapsulation layer.

According to some embodiments, after forming the element layer, at least one dam portion surrounding the display area is in the dam area. According to some embodiments, forming the second encapsulation layer comprises a process of dropping a liquid organic insulating material on the first encapsulation layer, a process of spreading the organic insulating material into an area surrounded by the at least one dam portion, and a process of curing the organic insulating material. According to some embodiments, in the process of spreading the organic insulating material, some of the organic insulating material overflowing into the junction area spreads into a part of the junction area between the dam area and the groove, and is accommodated on a part of the first encapsulation layer which overlaps the groove.

According to some embodiments, in the providing of the substrate, the substrate comprises a main region comprising the display area and the non-display area, and a sub-region protruding from one side of the main region. According to some embodiments, in forming the groove, the groove faces the other sides except one side connected to the sub-region in the edge of the main region.

According to some embodiments, in forming the first crack dam, first contact holes are further formed. In forming the groove, second contact holes are further formed. According to some embodiments, each of the first contact holes reaches one of the first semiconductor layer, the first gate conductive layer, and the second gate conductive layer. According to some embodiments, each of the second contact holes reaches one of the second semiconductor layer and the third gate conductive layer.

According to some embodiments, forming the circuit layer further comprises after forming the groove, forming a first source-drain conductive layer on the second interlayer insulating layer; forming a first planarization layer covering the first source-drain conductive layer by stacking an organic insulating material on the second interlayer insulating layer; forming a second source-drain conductive layer on the first planarization layer; and forming a second planarization layer covering the second source-drain conductive layer by stacking an organic insulating material on the first planarization layer. According to some embodiments, forming the element layer comprises forming anode electrodes in the emission areas; forming a pixel defining layer covering edges of the anode electrodes in a non-emission area between the emission areas, and forming a spacer layer on a part of the pixel defining layer; forming light emitting layers on the anode electrodes; and forming a cathode electrode on the pixel defining layer, the spacer layer, and the light emitting layers. Each of the at least one dam portion comprises two or more dam layers which are sequentially stacked. According to some embodiments, each of the two or more dam layers is the same layer as one of the first planarization layer, the second planarization layer, the pixel defining layer, and the spacer layer.

According to some embodiments, a display device according to some embodiments includes a substrate, a circuit layer on the substrate, and an element layer on the circuit layer.

According to some embodiments, the substrate includes a display area in which emission areas are arranged, and a non-display area around the display area.

According to some embodiments, the non-display area includes a dam area spaced apart from the display area and in which at least one dam portion surrounding the display area is arranged, and a junction area surrounding the dam area.

According to some embodiments, the circuit layer includes a barrier layer on the substrate, a buffer layer on the barrier layer, and two or more inorganic insulating layers on the buffer layer and containing an inorganic insulating material.

According to some embodiments, the display device according to some embodiments further includes a groove that is in a part of the junction area, is spaced apart from the dam area and the edge of the substrate, and penetrates the barrier layer and the buffer layer.

According to some embodiments, the display device according to some embodiments may further include an encapsulation layer on the element layer, and a touch sensor layer on the encapsulation layer.

According to some embodiments, the encapsulation layer may include a first encapsulation layer on the element layer and containing an inorganic insulating material, a second encapsulation layer in the display area on the first encapsulation layer and containing an organic insulating material, and a third encapsulation layer covering the second encapsulation layer and containing an inorganic insulating material.

According to some embodiments, some of the organic insulating material of the second encapsulation layer which overflows to the junction area may spread to a part of the junction area between the dam area and the groove, and may be accommodated on a part of the first encapsulation layer that overlaps the groove.

That is, some of the organic insulating material overflowing to the junction area is accommodated in the groove, and thus may not spread to the edge of the substrate.

Therefore, lifting defects caused by the organic insulating material overflowing to the junction area may be prevented or reduced.

However, the characteristics of embodiments of the present disclosure are not limited to those described above and various other characteristics are incorporated herein.

### BRIEF DESCRIPTION OF THE DRAWINGS

The above and other aspects and features of some embodiments of the

present disclosure will become more apparent by describing in more detail aspects of some embodiments thereof with reference to the attached drawings, in which:

FIG. 1 is a perspective view illustrating a display device according to some embodiments;

FIG. 2 is a plan view illustrating the display device of FIG. 1;

FIG. 3 is a cross-sectional view taken along the line A-A′ of FIG. 2;

FIG. 4 is a layout diagram showing part B of FIG. 2 according to some embodiments;

FIG. 5 is an equivalent circuit diagram showing the light emitting pixel driver of FIG. 4;

FIG. 6 is a plan view illustrating the touch sensor layer of FIG. 3;

FIG. 7 is an enlarged view showing part C of FIG. 6;

FIG. 8 is a cross-sectional view taken along the line D-D′ of FIG. 7;

FIG. 9 is a plan view illustrating the substrate of FIG. 2 according to some embodiments;

FIGS. 10, 11, 12, and 13 are cross-sectional views taken along the line E-E′ of FIG. 9 according to some embodiments;

FIGS. 14 and 15 are a flowchart illustrating a method for manufacturing the display device according to some embodiments; and

FIGS. 16 to 28 are process views illustrating the manufacturing method of FIGS. 14 and 15 according to some embodiments.

### DETAILED DESCRIPTION

Aspects of some embodiments of the present disclosure will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and/or vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, operations, operations, elements and/or components, but do not preclude the presence or addition of other features, integers, operations, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the spirit and scope of the present disclosure herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, aspects of some embodiments will be described in more detail with reference to the accompanying drawings.

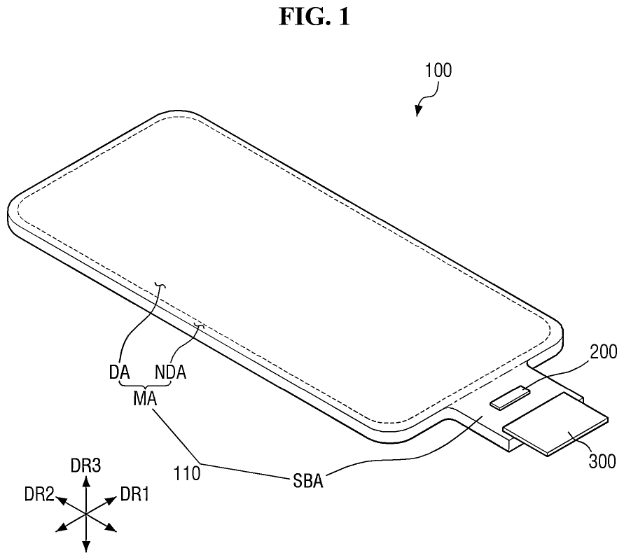

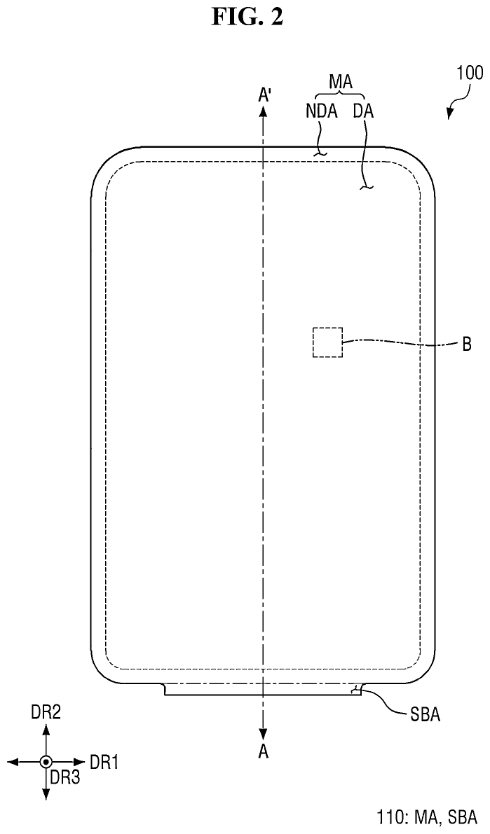

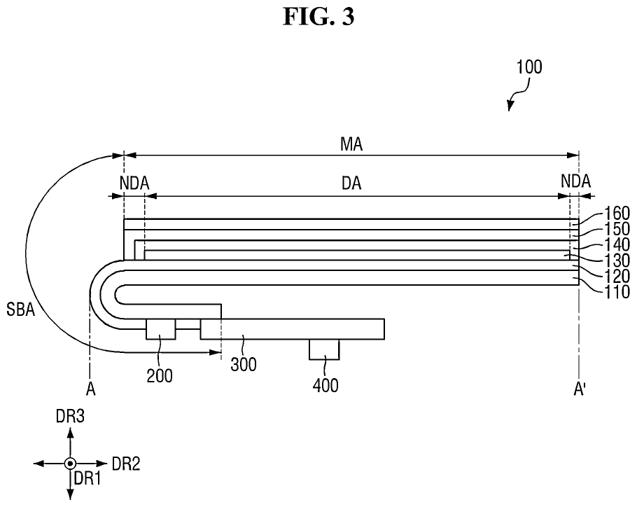

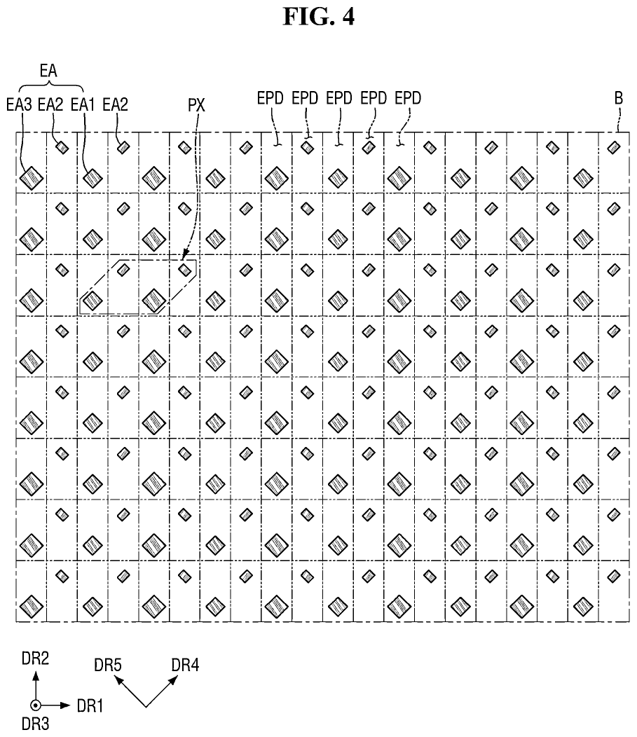

FIG. 1 is a perspective view illustrating a display device according to some embodiments. FIG. 2 is a plan view illustrating the display device of FIG. 1. FIG. 3 is a cross-sectional view taken along the line A-A′ of FIG. 2. FIG. 4 is a layout diagram showing part B of FIG. 2 according to some embodiments.

Referring to FIG. 1, a display device 100 is a device for displaying a moving image or a still image. The display device 100 may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

The display device 100 may be a light emitting display device such as an organic light emitting display using an organic light emitting diode, a quantum dot light emitting display including a quantum dot light emitting layer, an inorganic light emitting display including an inorganic semiconductor, and a micro light emitting display using a micro or nano light emitting diode (LED). Hereinafter, a case in which the display device 100 is an organic light emitting display device will be mainly described, but the present disclosure may be applied to a display device including an organic insulating material, an organic light emitting material, and a metal material.

The display device 100 may be formed to be flat, but embodiments according to the present disclosure are not limited thereto. For example, the display device 100 may include a curved portion formed at left and right ends and having a constant curvature or a varying curvature. In addition, the display device 100 may be formed to be flexible so that it can be curved, bent, folded, or rolled without damaging the display device 100.

The display device 100 may include a substrate 110, a display driving circuit 200, and a circuit board 300.

The substrate 110 may include a main region MA located on one surface (hereinafter, referred to as a display surface) where an image is displayed, and a sub-region SBA protruding from one side of the main region MA.

The main region MA may include a display area DA in which emission areas EA (see FIG. 4) emitting light with respective colors and luminances are arranged for displaying images, and a non-display area NDA arranged around (e.g., in a periphery or outside a footprint of) the display area DA.

A part of the sub-region SBA may be transformed to be bent, so that another part of the sub-region SBA may face the rear surface of the substrate 110 and overlap the main region MA.

FIG. 1 illustrates a state in which the sub-region SBA is unfolded to be located side by side with the main region MA. On the other hand, FIGS. 2 and 3 illustrate a state in which a part of the sub-region SBA is bent.

Referring to FIG. 2, the display area DA may, in a plan view, be formed in a rectangular shape having short sides in a first direction DR1 and long sides in the second direction DR2 crossing the first direction DR1. The corner where the short side in the first direction DR1 and the long side in the second direction DR2 meet may be rounded to have a curvature (e.g., a set or predetermined curvature) or may be right-angled. The planar shape of the display area DA is not limited to the rectangular shape, and may be formed in another polygonal shape, a circular shape or an elliptical shape.

The display area DA may occupy most of the main region MA. The display area DA may be located at the center of the main region MA.

Referring to FIG. 3, the display device 100 according to some embodiments may include the substrate 110 including the display area DA and the non-display area NDA, a circuit layer 120 located on the substrate 110, and an element layer 130 located on the circuit layer 120.

The display device 100 according to some embodiments may further include an encapsulation layer 140 located on the element layer 130, and a touch sensor layer 150 located on the encapsulation layer 140.

The display device 100 according to some embodiments may further include a polarization layer 160 located on the touch sensor layer 150 and overlapping the element layer 130.

The substrate 110 may be formed of an insulating material such as a polymer resin. For example, the substrate 110 may be formed of polyimide. The substrate 110 may be a flexible substrate which can be bent, folded or rolled.

Alternatively, the substrate 110 may be formed of an insulating material such as glass or the like.

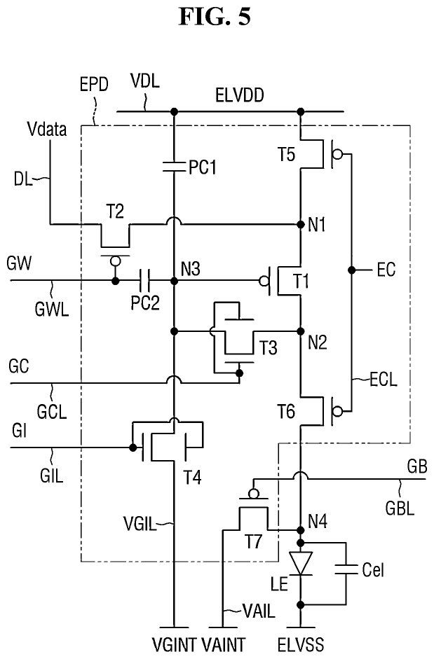

The element layer 130 may include light emitting elements LE (see FIG. 5) respectively located in the emission areas EA.

The circuit layer 120 may include light emitting pixel drivers EPD (see FIG. 4) electrically connected to the light emitting elements LE of the element layer 130, respectively.

The encapsulation layer 140 may cover the element layer 130 and may extend into the non-display area NDA to be contact with the circuit layer 120. The encapsulation layer 140 may include a structure in which two or more inorganic layers and at least one organic layer are alternately stacked.

The touch sensor layer 150 may be located in the main region MA on the encapsulation layer 140. The touch sensor layer 150 may include touch electrodes for sensing a touch of a person or an object.

The polarization layer 160 blocks external light reflected from the touch sensor layer 150, the encapsulation layer 140, the element layer 130, and the circuit layer 120, and the interfaces thereof, and this is to prevent or reduce the deterioration of visibility of images due to external light reflection.

The display device 100 may further include a cover window located on the polarization layer 160. The cover window may be attached to the polarization layer 160 by a transparent adhesive member such as an optically clear adhesive (OCA) film or an optically clear resin (OCR). The cover window may be made of an inorganic material such as glass, or an organic material such as plastic or a polymer material. Due to the cover window, the touch sensor layer 150, the encapsulation layer 140, the element layer 130, and the circuit layer 120 may be protected from electrical and physical impact on the display surface.

The display driving circuit 200 may be provided as an integrated circuit chip (IC).

The display driving circuit 200 may be mounted on the sub-region SBA of the substrate 110 by a chip on glass (COG) method, a chip on plastic (COP) method, or an ultrasonic bonding method, but is not limited thereto.

For example, the display driving circuit 200 may be attached onto the circuit board 300 by a chip on film (COF) method.

The display driving circuit 200 may supply data signals to data lines DL (see FIG. 5) of the circuit layer 120 (see FIG. 3).

The circuit board 300 may be a flexible printed circuit board, a printed circuit board, or a flexible film such as a chip on film.

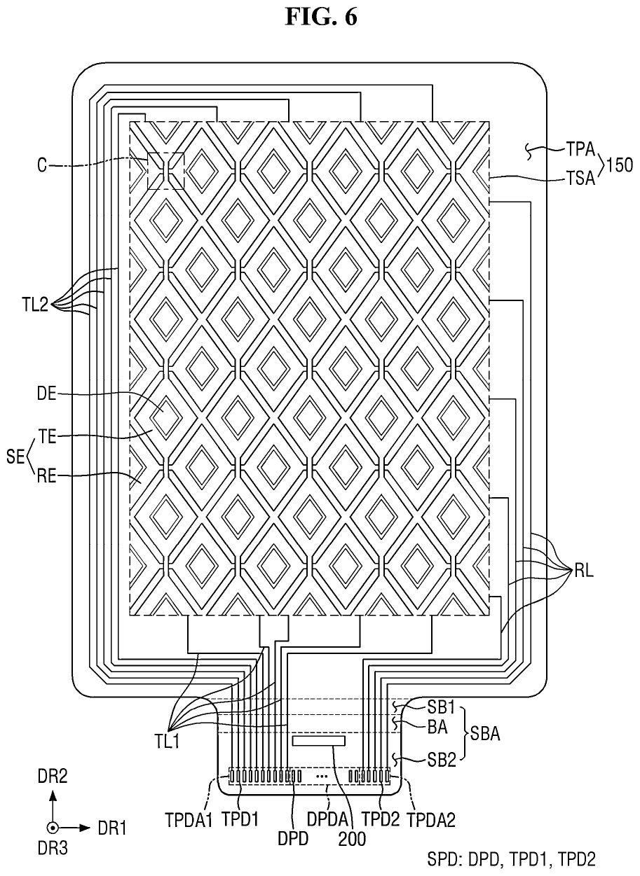

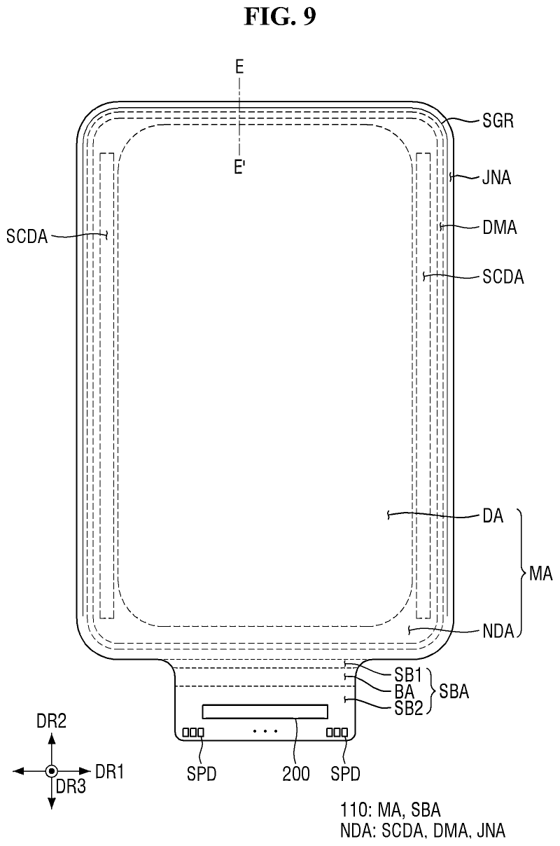

The circuit board 300 may be bonded to signal pads SPD (see FIGS. 6 and 9) located at the edge of the sub-region SBA of the substrate 110 using a low-resistance and high-reliability material such as an anisotropic conductive film or SAP, and may be electrically connected to the circuit layer 120.

The display device 100 may further include a touch driving circuit 400 for driving the touch sensor layer 150.

The touch driving circuit 400 may be prepared as an integrated circuit chip (IC) and mounted on the circuit board 300.

The touch driving circuit 400 may apply a touch driving signal to a plurality of driving electrodes provided on the touch sensor layer 150, receive a touch sensing signal of each of a plurality of touch nodes through a plurality of sensing electrodes, and sense a charge change amount of mutual capacitance based on the touch sensing signal.

That is, the touch driving circuit 400 may determine whether the user's touch has been made, whether the user is in proximity, and so forth, according to the touch sensing signal of each of the plurality of touch nodes. The user's touch refers to a direct contact of an object such as a pen or a user's finger with the front surface of the display device 100. The user's approach means that an object such as a pen or a user's finger is positioned away from the front surface of the display device 100, such as hovering.

Referring to FIG. 4, the display area DA of the display device 100 may include the emission areas EA. In addition, the display area DA may further include a non-emission area located in a gap between the emission areas EA.

The light emitting pixel drivers EPD that are respectively electrically connected to the light emitting elements LE of the emission areas EA may be arranged side by side in the main region MA in the first direction DR1 and the second direction DR2. The light emitting pixel drivers EPD may be respectively electrically connected to light emitting elements LE (see FIG. 5) of the element layer 130 respectively located in the emission areas EA.

The emission areas EA may have a rhombus shape or a rectangular shape in plan view. However, this is only an example, and the planar shape of the emission areas EA is not limited to that illustrated in FIG. 4. That is, in a plan view, the emission areas EA may have a polygonal shape such as a square, a pentagon, a hexagon, etc., or may have a circular or elliptical shape including the edge of a curve.

The emission areas EA may include first emission areas EA1 emitting light of a first color in a wavelength band (e.g., a set or predetermined wavelength band), second emission areas EA2 emitting light of a second color in a wavelength band lower than that of the first color, and third emission areas EA3 emitting light of a third color in a wavelength band lower than that of the second color.

For example, the first color may be red having a wavelength band of approximately 600 nm to 750 nm. The second color may be green having a wavelength band of 480 nanometers (nm) to 560 nm (or approximately 480 nm to 560 nm). The third color may be blue having a wavelength band of 370 nm to 460 nm (or approximately 370 nm to 460 nm).

The first emission areas EA1 and the third emission areas EA3 may be alternately arranged in at least one of the first direction DR1 or the second direction DR2.

The second emission areas EA2 may be arranged side by side in at least one of the first direction DR1 or the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixels PX may be a basic unit for displaying various colors including white with a luminance (e.g., a set or predetermined luminance).

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

FIG. 5 is an equivalent circuit diagram showing the light emitting pixel driver of FIG. 4.

Referring to FIG. 5, one of the light emitting elements LE of the element layer 130 may be electrically connected between one of the light emitting pixel drivers EPD of the circuit layer 120 and a second power ELVSS.

That is, the anode electrode of the light emitting element LE is electrically connected to the light emitting pixel driver EPD, and the cathode electrode of the light emitting element LE may be applied with a second power ELVSS lower than a first power ELVDD.

A capacitor Cel connected in parallel with the light emitting element LE refers to a parasitic capacitance between the anode electrode and the cathode electrode.

The circuit layer 120 may further include a first power line VDL that transmits the first power ELVDD, a gate initialization power line VGIL that transmits a gate initialization power VGINT, and an anode initialization power line VAIL that transmits an anode initialization power VAINT.

The circuit layer 120 may further include a scan write line GWL for transmitting a scan write signal GW, a scan initialization line GIL for transmitting a scan initialization signal GI, an emission control line ECL for transmitting an emission control signal EC, a gate control line GCL for transmitting a gate control signal GC, and a bias control line GBL for transmitting a bias control signal GB.

One light emitting pixel driver EPD of the circuit layer 120 may include a first transistor T1 configured to generate a driving current for driving the light emitting element LE, two or more transistors T2 to T7 electrically connected to the first transistor T1, and at least one capacitor PC1.

The first transistor T1 is connected in series with the light emitting element LE between the first power ELVDD and the second power ELVSS.

The first transistor T1 may be electrically connected between the first node N1 and the second node N2. The first node N1 is electrically connected to the first electrode (e.g., source electrode) of the first transistor T1. The second node N2 is electrically connected to the second electrode (e.g., drain electrode) of the first transistor T1.

In other words, the first electrode (e.g., the source electrode) of the first transistor T1 may be electrically connected to the first power line VDL through the fifth transistor T5. Further, the second electrode (e.g., the drain electrode) of the first transistor T1 may be electrically connected to the anode electrode of the light emitting element LE through the sixth transistor T6.

The first pixel capacitor PC1 may be electrically connected between the first power line VDL and a third node N3. The third node N3 is electrically connected to the gate electrode of the first transistor T1.

That is, the gate electrode of the first transistor T1 may be electrically connected to the first power line VDL through the first capacitor PC1.

Accordingly, the potential of the gate electrode of the first transistor T1 may be maintained at the voltage charged in the first power line VDL.

The second transistor T2 may be electrically connected between the data line DL and the first node N1.

In other words, the second transistor T2 may be electrically connected between the first electrode of the first transistor T1 and the data line DL. The second transistor T2 may be turned on by the scan write signal GW of the scan write line GWL.

That is, the first electrode of the first transistor T1 may be electrically connected to the data line DL through the second transistor T2.

The fifth transistor T5 may be electrically connected between the first node N1 and the first power line VDL.

The sixth transistor T6 may be electrically connected between the second node N2 and the fourth node N4. The fourth node N4 is electrically connected to the anode electrode of the light emitting element LE.

That is, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

When a data signal Vdata of the data line DL is transmitted to the first electrode of the first transistor T1 through the turned-on second transistor T2, the voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, i.e., the gate-to-source voltage difference becomes equal to or greater than a threshold voltage, the first transistor T1 may be turned on, thereby generating a drain-source current of the first transistor T1 corresponding to the data signal Vdata.

Then, when the fifth transistor T5 and the sixth transistor T6 are turned on, the first transistor T1 may be connected in series with the light emitting element LE between the first power line VDL and the second power line VSL. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1. The third transistor T3 may be turned on by the gate control signal GC of the gate control line GCL.

Through the turned-on third transistor T3, the voltage difference between the second node N2 and the third node N3 may be initialized.

The fourth transistor T4 may be electrically connected between the gate initialization voltage line VGIL and the third node N3. That is, the fourth transistor T4 may be connected between the gate electrode of the first transistor T1 and the gate initialization voltage line VGIL. The fourth transistor T4 may be turned on by the scan initialization signal GI of the scan initialization line GIL.

The potential of the third node N3 may be initialized through the turned-on fourth transistor T4.

The third transistor T3 and the fourth transistor T4 may be provided as N-type MOSFETs.

The seventh transistor T7 may be electrically connected between the fourth node N4 and the anode initialization power line VAIL. That is, the seventh transistor T7 may be electrically connected between the anode electrode of the light emitting element LE and the anode initialization voltage line VAIL. The seventh transistor T7 may be turned on by the bias control signal GB of the bias control line GBL.

The potential of the fourth node N4 may be initialized through the turned-on seventh transistor T7.

According to some embodiments, among the first to seventh transistors T1 to T7, the third transistor T3 and the fourth transistor T4 may be provided as N-type

MOSFETs, and the other transistors T1, T2, and T5 to T7 except the third transistor T3 and the fourth transistor T4 may be provided as P-type MOSFETs.

Accordingly, according to some embodiments, the circuit layer 120 may include a first semiconductor layer for providing a P-type MOSFET and a second semiconductor layer for providing an N-type MOSFET.

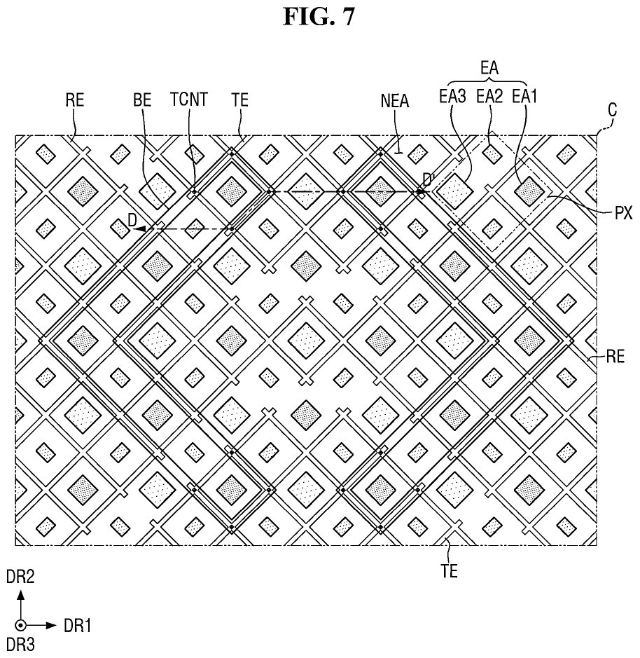

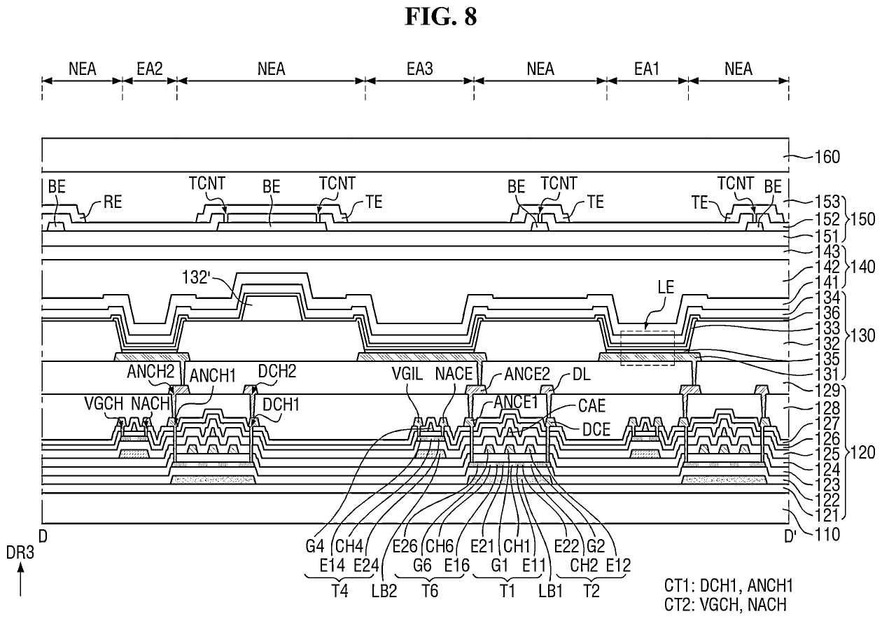

FIG. 6 is a plan view illustrating the touch sensor layer of FIG. 3. FIG. 7 is an enlarged view showing part C of FIG. 6. FIG. 8 is a cross-sectional view taken along the line D-D′ of FIG. 7.

FIG. 6 illustrates the touch sensor layer 150 of a capacitance method. In this case, the touch driving circuit 400 may sense a touch based on whether capacitance fluctuations. However, FIG. 6 is merely an example for easy description, and the touch sensor layer 150 according to some embodiments is not limited to that illustrated in FIG. 6.

FIG. 6 illustrates only some of the components of the touch sensor layer 150 for simplicity of description.

Referring to FIG. 6, the touch sensor layer 150 may be located in the main region MA. The touch sensor layer 150 may include a touch sensing area TSA for sensing a user's touch and a touch periphery area TPA around the touch sensing area TSA.

The touch sensing area TSA has a wider width than the display area DA and may be similar to the display area DA. Accordingly, the touch periphery area TPA, which is a periphery of the touch sensing area TSA, may be similar to the non-display area NDA, which is a periphery of the display area DA.

For example, the touch sensing area TSA may overlap the display area DA and the edge of the non-display area NDA in contact with the display area DA. In this case, the touch periphery area TPA may overlap the remaining part of the non-display area NDA that does not correspond to the touch sensing area TSA.

The touch sensor layer 150 may include sensor electrodes SE and dummy electrodes DE that are matrix-arranged in the touch sensing area TSA and generate mutual capacitance, and sensor lines TL1, TL2, and RL located in the touch periphery area TPA.

The sensor electrodes SE may include a driving electrode TE (touch driving electrode) to which a driving signal is applied, and a sensing electrode RE (receiving electrode) to sense a voltage charged in mutual capacitance with the driving electrode TE.

The sensor lines TL1, TL2, and RL may include a first driving line TL1, a second driving line TL2, and a sensing line RL.

Each of the first driving line TL1 and the second driving line TL2 may be electrically connected to two or more driving electrodes TE extending in the second direction DR2 among the driving electrodes TE.

The first driving line TL1 may extend from one side of the touch sensing area TSA in the second direction DR2, which faces the sub-region SBA, to the sub-region SBA.

The second driving line TL2 may extend from the other side of the touch sensing area TSA in the second direction DR2, which is far from the sub-region SBA, to the sub-region SBA. A part of the second driving line TL2 may extend in parallel with one side of the touch sensing area TSA in the first direction DR1.

The sensing line RL may be electrically connected to two or more sensing electrodes RE extending in the first direction DR1 among the sensing electrodes RE.

The sensing line RL may extend from the other side of the touch sensing area TSA in the first direction DR1 to the sub-region SBA.

The sensing electrodes RE may be arranged in parallel in the first direction DR1. The sensing electrodes RE adjacent in the first direction DR1 may be electrically connected to each other through a protruding portion in the first direction DR1.

The driving electrodes TE may be arranged in parallel in the second direction DR2. The driving electrodes TE adjacent in the second direction DR2 may be electrically connected to each other through a bridge electrode BE (see FIG. 7) in the second direction DR2.

Each of the driving electrodes TE and the sensing electrodes RE may have a shape surrounding the dummy electrode DE located in the center thereof.

Each of the dummy electrodes DE may be spaced apart from the driving electrode TE or the sensing electrode RE that surrounds it. The dummy electrode DE may be maintained in a floating state.

Although FIG. 6 illustrates that each of the driving electrode TE, the sensing electrode RE, and the dummy electrode DE has a rhombic planar shape, embodiments according to the present disclosure are not limited to that illustrated in FIG. 6. For example, the planar shape of the driving electrode TE, the sensing electrode RE, and the dummy electrode DE may be a quadrilateral shape other than a rhombus, a polygonal shape other than a quadrilateral shape, a circular shape, or an elliptical shape.

The display device 100 according to some embodiments may include signal pads SPD located in a second sub-region SB2 and connected to the circuit board 300.

The signal pads SPD may include display signal pads DPD transmitting and receiving signals to drive the circuit layer 120, and touch signal pads TPD1 and TPD2 transmitting and receiving signals to drive the touch sensor layer 150.

For example, the second sub-region SB2 may include a display pad area DPDA adjacent to the display driving circuit 200, and a first touch pad area TPDA1 and a second touch pad area TPDA2 located on both sides of the display pad area DPDA.

For example, the display signal pads DPD for transmitting and receiving signals that are transmitted to the circuit layer 120 or the display driving circuit 200 may be located in the display pad area DPDA.

The first touch pads TPD1 electrically connected to the first driving line TL1 and the second driving line TL2, respectively, may be located in the first touch pad area TPDA1.

The second touch pads TPD2 electrically connected to the sensing line RL, respectively, may be located in the second touch pad area TPDA2.

Referring to FIG. 7, the driving electrode TE and the sensing electrode RE may be spaced apart from each other.

The bridge electrode BE may electrically connect the driving electrodes TE adjacent in the second direction DR2.

Although FIG. 7 illustrates the bridge electrode BE having a shape including at least one bend, the shape of the bridge electrode BE according to some embodiments is not limited to that illustrated in FIG. 7.

The driving electrodes TE adjacent in the second direction DR2 may be electrically connected to each other through two or more bridge electrodes BE. In this way, reliability of the electrical connection between the driving electrodes TE may be improved.

Although FIG. 7 illustrates that two bridge electrodes BE parallel to each other are located between the driving electrodes TE adjacent to each other in the second direction DR2, embodiments according to the present disclosure are not limited to that illustrated in FIG. 7.

The bridge electrode BE may be electrically connected to the driving electrodes TE through touch contact holes TCNT.

The touch contact holes TCNT may extend to the bridge electrode BE through a touch interlayer insulating layer 152.

The driving electrode TE, the sensing electrode RE, and the bridge electrode BE may have a mesh or net structure in plan view. The dummy electrodes DE may also have a mesh or net structure in plan view. In this way, because the overlapping width of the driving electrode TE, the sensing electrode RE, the dummy electrode DE, and the bridge electrode BE in the emission areas EA may be reduced, a decrease in light emission efficiency due to the driving electrode TE, the sensing electrode RE, the dummy electrode DE, and the bridge electrode BE may be reduced.

Referring to FIG. 8, the display device 100 according to some embodiments may include the substrate 110, the circuit layer 120 on the substrate 110, and the element layer 130 on the circuit layer 120.

The display device 100 according to some embodiments may further include the encapsulation layer 140 on the element layer 130, and the touch sensor layer 150 on the encapsulation layer 140.

The substrate 110 may be made of a material having a flexible characteristic capable of bending, folding, rolling, or the like.

The substrate 110 may include the display area DA where the emission areas EA are arranged, and the non-display area NDA arranged around (e.g., in a periphery or outside a footprint of) the display area DA.

The substrate 110 may include the main region MA including the display area DA and the non-display area NDA, and the sub-region SBA protruding from one side of the main region MA.

The circuit layer 120 may include the light emitting pixel drivers EPD respectively corresponding to the emission areas EA.

Each of the light emitting pixel drivers EPD may include the transistors T1 to T7 (see FIG. 5) and at least one capacitor PC1 (see FIG. 5).

FIG. 8 shows the first transistor T1, the second transistor T2, the fourth transistor T4, and the sixth transistor T6 among the transistors T1 to T7 (see FIG. 5) of the light emitting pixel driver EPD.

According to some embodiments, the circuit layer 120 may include a barrier layer 121 located on the substrate 110, a buffer layer 122 located on the barrier layer 121, and two or more inorganic insulating layers 123 to 127 located on the buffer layer 122 and containing an inorganic insulating material.

The buffer layer 122 may cover a first light blocking layer LB1 on the barrier layer 121.

The two or more inorganic insulating layers 123 to 127 may include a first gate insulating layer 123 located on the buffer layer 122, a second gate insulating layer 124 located on the first gate insulating layer 123, a first interlayer insulating layer 125 located on the second gate insulating layer 124, a third gate insulating layer 126 located on the first interlayer insulating layer 125, and a second interlayer insulating layer 127 located on the third gate insulating layer 126.

The first gate insulating layer 123 may cover a first semiconductor layer CH1, E11, E21, CH2, E12, E22, CH6, E16, and E26 on the buffer layer 122.

The second gate insulating layer 124 may cover a first gate conductive layer G1, G2, and G6 on the first gate insulating layer 123.

The first interlayer insulating layer 125 may cover a second gate conductive layer CAE and LB2 on the second gate insulating layer 124.

The third gate insulating layer 126 may cover a second semiconductor layer CH4, E14, and E24 on the first interlayer insulating layer 125.

The second interlayer insulating layer 127 may cover a third gate conductive layer G4 on the third gate insulating layer 126.

According to some embodiments, the circuit layer 120 may further include a first planarization layer 128 covering a first source-drain conductive layer VGIL, NACE, DCE, and ANCE1 on the second interlayer insulating layer 126 and containing an organic insulating material, and a second planarization layer 129 covering a second source-drain conductive layer ANCE2 and DL on the first planarization layer 128 and containing an organic insulating material.

In other words, the circuit layer 120 of the display device 100 according to some embodiments may include the barrier layer 121 located on the substrate 110, the buffer layer 122 located on the barrier layer 121 and covering the first light blocking layer LB1, the first semiconductor layer CH1, E11, E21, CH2, E12, E22, CH6, E16, and E26 located on the buffer layer 122, the first gate insulating layer 123 covering the first semiconductor layer, the first gate conductive layer G1, G2, and G6 located on the first gate insulating layer 123, the second gate insulating layer 124 covering the first gate conductive layer, the second gate conductive layer CAE and LB2 located on the second gate insulating layer 124, the first interlayer insulating layer 125 covering the second gate conductive layer, the second semiconductor layer CH4, E14, and E24 located on the first interlayer insulating layer 125, the third gate insulating layer 126 covering the second semiconductor layer, the third gate conductive layer G4 located on the third gate insulating layer 126, the second interlayer insulating layer 127 covering the third gate conductive layer, the first source-drain conductive layer ANCE1, VGIL, and DCE located on the second interlayer insulating layer 127, the first planarization layer 128 covering the first source-drain conductive layer, the second source-drain conductive layer DL and ANCE2 located on the first planarization layer 128, and the second planarization layer 129 covering the second source-drain conductive layer.

The barrier layer 121 and the buffer layer 122 may contain different inorganic insulating materials.

The first semiconductor layer on the buffer layer 122 may include the channel portions CH1, CH2, and CH6, the first electrode portions E11, E12, and E16, and the second electrode portions E21, E22, and E26 of the first transistor T1, the second transistor T2, the fifth transistor T5 (see FIG. 5), the sixth transistor T6, and the seventh transistor T7 that are provided as P-type MOSFETs.

The first gate conductive layer on the first gate insulating layer 123 may include the gate electrodes G1, G2, and G6 of the first transistor T1, the second transistor T2, the fifth transistor T5 (see FIG. 5), the sixth transistor T6, and the seventh transistor T7 that are provided as P-type MOSFETs.

Since the fifth transistor T5 and the seventh transistor T7 have the same structure as those of the first transistor T1, the second transistor T2, and the sixth transistor T6, the redundant description will be omitted below.

In each of the first transistor T1, the second transistor T2, and the sixth transistor T6, the channel portions CH1, CH2, and CH6 may overlap the gate electrodes G1, G2, and G6.

The channel portion CH1 of the first transistor T1 may overlap the first light blocking layer LB1 on the barrier layer 121.

In each of the first transistor T1, the second transistor T2, and the sixth transistor T6, the first electrode portions E11, E12, and E16 may be connected to one ends of the channel portions CH1, CH2, and CH6, and the second electrode portions E21, E22, and E26 may be connected to the other ends of the channel portions CH1, CH2, and CH6.

The first electrode portion E11 of the first transistor T1 may be connected to the second electrode portion E22 of the second transistor T2.

The second electrode portion E21 of the first transistor T1 may be connected to the first electrode portion E16 of the sixth transistor T6.

The second gate conductive layer on the second gate insulating layer 124 may include the capacitor electrode CAE and the second light blocking layer LB2.

The capacitor electrode CAE may overlap the gate electrode G1 of the first transistor T1.

Accordingly, the first pixel capacitor PC1 (see FIG. 5) may be provided by the overlapping area between the capacitor electrode CAE and the gate electrode G1 of the first transistor T1.

The second semiconductor layer on the first interlayer insulating layer 125 may include the channel portion CH4, the first electrode portion E14, and the second electrode portion E24 of the third transistor T3 (see FIG. 5) and the fourth transistor T4 that are provided as N-type MOSFETs.

The third gate conductive layer on the third gate insulating layer 126 may include the gate electrode G4 of each of the third transistor T3 (see FIG. 5) and the fourth transistor T4 that are provided as N-type MOSFETs.

In each of the third transistor T3 (see FIG. 5) and the fourth transistor T4, the channel portion CH4 may overlap the second light blocking layer LB2.

Since the third transistor T3 has the same structure as that of the fourth transistor T4, the redundant description will be omitted below.

The channel portion CH4 of the fourth transistor T4 may overlap the gate electrode G4 of the fourth transistor T4.

The first electrode portion E14 of the fourth transistor T4 may be connected to one end of the channel portion CH4 of the fourth transistor T4, and the second electrode portion E24 of the fourth transistor T4 may be connected to the other end of the channel portion CH4 of the fourth transistor T4.

The first source-drain conductive layer on the second interlayer insulating layer 127 may include the first anode connection electrode ANCE1, the data connection electrode DCE, the gate initialization voltage line VGIL, and the node auxiliary connection electrode NACE.

The second source-drain conductive layer on the first planarization layer 128 may include the second anode connection electrode ANCE2 and the data line DL.

The data connection electrode DCE may be electrically connected to the first electrode portion E12 of the second transistor T2 through a first data connection hole DCH1.

The data line DL may be electrically connected to the data connection electrode DCE through a second data connection hole DCH2.

Accordingly, the data line DL may be electrically connected to the first electrode portion E12 of the second transistor T2 through the data connection electrode DCE.

An anode electrode 131 of the element layer 130 may be located on the second planarization layer 129.

The first anode connection electrode ANCE1 may be electrically connected to the second electrode portion E26 of the sixth transistor T6 through a first anode connection hole ANCH1.

The second anode connection electrode ANCE2 may be electrically connected to the first anode connection electrode ANCE1 through a second anode connection hole ANCH2.

The anode electrode 131 may be electrically connected to the second anode connection electrode ANCE2 through a third anode connection hole ANCH3.

Accordingly, the anode electrode 131 may be electrically connected to the second electrode portion E26 of the sixth transistor T6 through the first anode connection electrode ANCE1 and the second anode connection electrode ANCE2.

Each of the first data connection hole DCH1 and the first anode connection hole ANCH1 may penetrate the second interlayer insulating layer 127, the third gate insulating layer 126, the first interlayer insulating layer 125, the second gate insulating layer 124, and the first gate insulating layer 123.

The first contact holes CT1 may extend from the second interlayer insulating layer 127 to one of the first semiconductor layer, the first gate conductive layer, and the second gate conductive layer.

That is, the first data connection hole DCH1 and the first anode connection hole ANCH1 extend from the second interlayer insulating layer 127 to the first semiconductor layer, and thus may be included in the first contact holes CT1.

Each of the second anode connection hole ANCH2 and the second data connection hole DCH2 may penetrate the first planarization layer 128.

The gate initialization voltage line VGIL may be electrically connected to the first electrode portion E14 of the fourth transistor T4 through a gate initialization voltage connection hole VGCH.

The node auxiliary connection electrode NACE may be electrically connected to the second electrode portion E24 of the fourth transistor T4 through a node auxiliary connection hole NACH.

Second contact holes CT2 may extend from the second interlayer insulating layer 127 to one of the second semiconductor layer and the third gate conductive layer.

Each of the gate initialization voltage connection hole VGCH and the node auxiliary connection hole NACH may penetrate the second interlayer insulating layer 127 and the third gate insulating layer 126.

The second contact holes CT2 may extend from the second interlayer insulating layer 127 to one of the second semiconductor layer and the third gate conductive layer.

That is, the gate initialization voltage connection hole VGCH and the node auxiliary connection hole NACH extend from the second interlayer insulating layer 127 to the second semiconductor layer, and thus may be included in the second contact holes CT2.

The element layer 130 on the circuit layer 120 may include the light emitting elements LE respectively located in the emission areas EA1, EA2, and EA3.

Each of the light emitting elements LE may include a structure in which a light emitting layer 133 is located between the anode electrode 131 and a cathode electrode 134 facing each other.

According to some embodiments, the element layer 130 may include the anode electrodes 131 respectively located in the emission areas EA, a pixel defining layer 132 located in the non-emission area NEA and covering the edge of the anode electrode 131, a spacer layer 132′ located on a part of the pixel defining layer 132, the light emitting layers 133 respectively located on the anode electrodes 131, and the cathode electrode 134 located on the light emitting layers 133, the pixel defining layer 132, and the spacer layer 132′.

Alternatively, each of the light emitting elements LE may further include first common layers 135 located between the anode electrodes 131 and the light emitting layers 133, and a second common layer 136 located between the light emitting layers 133 and the cathode electrode 134.

The encapsulation layer 140 may be located on the circuit layer 120 and cover the element layer 130.

The encapsulation layer 140 is to block the permeation of oxygen or moisture into the element layer 130 and to reduce electrical or physical impact to the circuit layer 120 and the element layer 130.

The encapsulation layer 140 may include a first encapsulation layer 141 located on the circuit layer 120, covering the element layer 130, and including an inorganic insulating material, a second encapsulation layer 142 located on the first encapsulation layer 141, overlapping the element layer 130, and including an organic insulating material, and a third encapsulation layer 143 located on the first encapsulation layer 141, covering the second encapsulation layer 142, and including an inorganic insulating material.

The touch sensor layer 150 may be located on the encapsulation layer 140.

According to some embodiments, the touch sensor layer 150 may include a touch buffer layer 151 located on the encapsulation layer 140, a touch interlayer insulating layer 152 located on the touch buffer layer 151, and a touch planarization layer 153 located on the touch interlayer insulating layer 152.

The touch interlayer insulating layer 152 may cover the bridge electrode BE on the touch buffer layer 151.

The touch planarization layer 153 may cover the driving electrode TE and the sensing electrode RE on the touch interlayer insulating layer 152.

Each of the touch buffer layer 151 and the touch interlayer insulating layer 152 may contain an inorganic insulating material.

The touch planarization layer 153 may contain an organic insulating material. For example, the touch planarization layer 153 may be made of a negative photoresist material that may be formed by a low-temperature process.

The polarization layer 160 may be located on the touch sensor layer 150.

For example, the polarization layer 160 may be attached to the touch planarization layer 153 through an adhesive layer between the polarization layer 160 and the touch planarization layer 153.

FIG. 9 is a plan view illustrating the substrate of FIG. 2 according to some embodiments.

Referring to FIG. 9, the substrate 110 of the display device 100 according to some embodiments may include the main region MA corresponding to the display surface, and the sub-region SBA protruding from one side of the main region MA.

The main region MA may include the display area DA in which emission areas EA are arranged, and the non-display area NDA arranged around the display area DA.

The non-display area NDA may include a dam area DMA spaced apart from the display area DA and surrounding the display area DA, and a junction area JNA located between the edge of the substrate 110 and the dam area DMA.

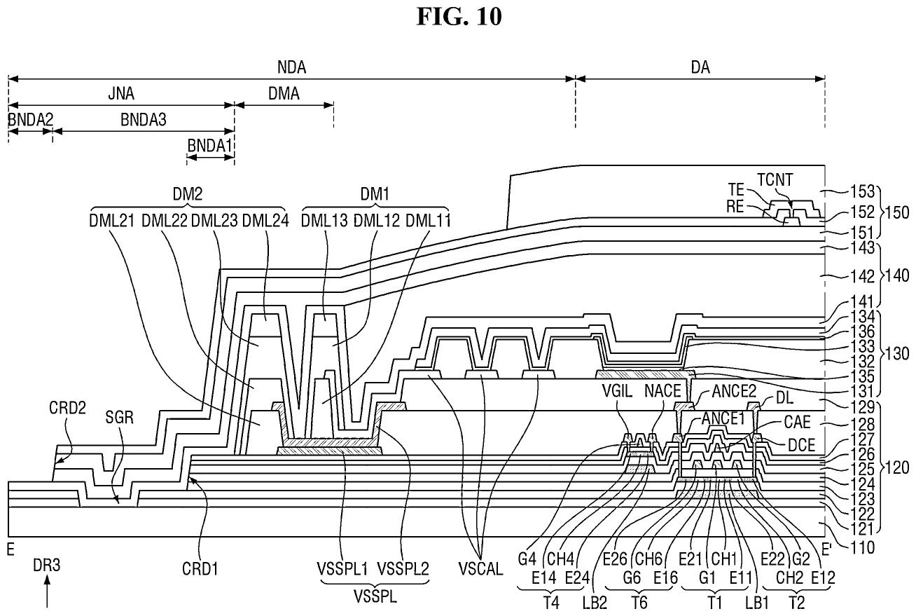

One or more dam portions DM1 and DM2 (see FIG. 10) surrounding the display area DA may be arranged in the dam area DMA.

At least one dam portion DAM is used for limiting an area where the organic insulating material of the second encapsulation layer 142 spreads widely. That is, the arrangement range of the second encapsulation layer 142 may be limited to the area surrounded by one or more dam portions DM1 and DM2.

In the junction area JNA, a junction structure of inorganic insulating materials may be arranged by sequentially stacking the inorganic insulating materials included in the circuit layer 120, the encapsulation layer 140, and the touch sensor layer 150.

The non-display area NDA may further include a scan driving circuit area SCDA located adjacent to at least one edge of the display area DA in the first direction DR1.

The circuit layer 120 may include a scan driving circuit located in the scan driving circuit area SCDA.

For example, the display driving circuit 200 or the circuit board 300 may supply a scan control signal to the scan driving circuit based on digital video data and timing signals.

The scan driving circuit of the scan driving circuit area SCDA may sequentially supply a signal to wires in the first direction DR1 based on the scan control signal.

For example, the wires in the first direction DR1 may include the scan write line GWL for transmitting the scan write signal GW, the scan initialization line GIL for transmitting the emission control signal EC, the gate control line GCL for transmitting the gate control signal GC, and the bias control line GBL for transmitting the bias control signal GB.

FIG. 9 illustrates a case in which the scan driving circuit area SCDA is a part of the non-display area NDA adjacent to both corners of the display area DA in the first direction DR1, but this is nothing more than an example.

The sub-region SBA may include a bending area BA that is transformed to be bent, and a first sub-region SB1 and the second sub-region SB2 that are respectively in contact with both sides of the bending area BA.

The first sub-region SB1 is located between the main region MA and the bending area BA. One side of the first sub-region SB1 may be in contact with the non-display area NDA of the main region MA, and the other side of the first sub-region SB1 may be in contact with the bending area BA.

The second sub-region SB2 is spaced apart from the main region MA with the bending area BA interposed therebetween, and is located on the bottom surface of the substrate 110 by the bending area BA transformed to be bent. That is, the second sub-region SB2 may overlap the main region MA in a thickness direction DR3 of the substrate 110 due to the bending area BA transformed to be bent.

One side of the second sub-region SB2 may be in contact with the bending area BA. The other side of the second sub-region SB2 may be in contact with a part of the edge of the substrate 110.

The signal pads SPD to which the circuit board 300 is connected, and the display driving circuit 200 may be located in the second sub-region SB2.

The display device 100 according to some embodiments further includes a groove SGR located in a part of the junction area JNA and spaced apart from the dam area DMA and the edge of the substrate 110.

According to some embodiments, the groove SGR may be a through groove that exposes the substrate 110 while penetrating at least one insulating layer extending to the edge of the substrate 110 among the insulating layers of the circuit layer 120. That is, the groove SGR may penetrate the buffer layer 122 and the barrier layer 121 covering the substrate 110.

Since the operationped portion is generated by the groove SGR, a part of the first encapsulation layer 141 located on the junction area JNA may include a groove in which the operationped portion of the groove SGR is replicated. Therefore, the organic insulating material of the second encapsulation layer 142 that has overflown to the junction area JNA is accommodated in the groove of the first encapsulation layer 141, and may not extend to the edge of the substrate 110.

The groove SGR according to some embodiments may be referred to as a storage valley, a storage groove, an accommodating groove, an auxiliary valley, an auxiliary groove, an auxiliary groove, or the like because it is a component for providing an auxiliary valley for accommodating the overflowed organic insulating material of the second encapsulation layer 142.

The groove SGR may face the other sides except one side connected to the sub-region SBA in the edge of the main region MA.

For example, when the edge of the main region MA includes first and second sides facing each other in the first direction DR1, and third and fourth sides facing each other in the second direction DR2, and the sub-region SBA is connected to the fourth side of the main region MA, the groove SGR may extend to face the first, third, and second sides in the edge of the main region MA.

This is to prevent or reduce instances of wires located between the sub-region SBA and one side of the display area DA facing the sub-region SBA being disconnected due to the groove SGR.

FIGS. 10, 11, 12, and 13 are cross-sectional views taken along the line E-E′ of FIG. 9 according to some embodiments.

Referring to FIG. 10, the circuit layer 120 of the display device 100 according to some embodiments may further include a second power supply line VSSPL that is located in the non-display area NDA and transmits the second power ELVSS (see FIG. 5), and a second power connection auxiliary line VSCAL electrically connected between the second power supply line VSSPL and the cathode electrode 134.

The second power supply line VSSPL may include a second power supply main line VSSPL1 located on the first source-drain conductive layer, and a second power supply sub-line VSSPL2 located on the second source-drain conductive layer.

The second power supply sub-line VSSPL2 may be electrically connected to the second power supply main line VSSPL1 through a connection hole penetrating the first planarization layer 128.

The second power connection auxiliary line VSCAL may be the same layer as the anode electrode 131.

The cathode electrode 134 may be electrically connected to the second power connection auxiliary line VSCAL through a hole where the pixel defining layer 132 is removed, and may be electrically connected to the second power supply line VSSPL through the second power connection auxiliary line VSCAL.

According to some embodiments, the display device 100 may further include one or more dam portions DM1 and DM2 located in the dam area DMA of the non-display area NDA.

The one or more dam portions DM1 and DM2 may respectively include two or more dam layers DML11, DML12, and DML13 and DML21, DML22, DML23, and DML24 that are sequentially stacked.

Each of the two or more dam layers DML11, DML12, and DML13 and DML21, DML22, DML23, and DML24 may be the same layer as one of one or more planarization layers 128 and 129 included in the circuit layer 120, and the pixel defining layer 132 and the spacer layer 132′ included in the element layer 130.

That is, each of the two or more dam layers DML11, DML12, and DML13 and DML21, DML22, DML23, and DML24 may be the same layer as one of the first planarization layer 128, the second planarization layer 129, the pixel defining layer 132 and the spacer layer 132′.

For example, the one or more dam portions DM1 and DM2 may include the first dam portion DM1 surrounding the display area DA and the second dam portion DM2 surrounding the first dam portion DM1.

The first dam portion DM1 may include the first dam layer DML11, the second dam layer DML12, and the third dam layer DML13 that are provided on the same layer as the second planarization layer 129, the pixel defining layer 132, and the spacer layer 132′.

The second dam portion DM2 may include the fourth dam layer DML21, the fifth dam layer DML22, the sixth dam layer DML23, and the seventh dam layer DML24 that are provided on the same layer as the first planarization layer 128, the second planarization layer 129, the pixel defining layer 132, and the spacer layer 132′.

According to some embodiments, the first planarization layer 128, the second planarization layer 129, the pixel defining layer 132, and the spacer layer 132′ containing an organic insulating material may be spaced apart from the dam area DMA.

Since the one or more dam portions DM1 and DM2 are located in the dam area DMA, the stacked structure of inorganic insulating materials may be located in the junction area JNA.

The barrier layer 121 and the buffer layer 122 may extend to the edge of the substrate 110.

The two or more inorganic insulating layers 123 to 127 located on the buffer layer 122 may extend to a first boundary area BNDA1 in contact with the dam area DMA in the junction area JNA. That is, the first gate insulating layer 123, the second gate insulating layer 124, the first interlayer insulating layer 125, the third gate insulating layer 126, and the second interlayer insulating layer 127 that are located on the buffer layer 122 may extend only to the first boundary area BNDA1 of the junction area JNA.

Accordingly, at the edge of the first boundary area BNDA1, the side surfaces of the two or more inorganic insulating layers 123 to 127 are exposed, so that a first crack dam CRD1 may be provided by the side surfaces of the two or more inorganic insulating layers 123 to 127.

In other words, the first crack dam CRD1 may be the operationped portion caused by the side surfaces of the first gate insulating layer 123, the second gate insulating layer 124, the first interlayer insulating layer 125, the third gate insulating layer 126, and the second interlayer insulating layer 127 that are located on the buffer layer 122.

Since the two or more inorganic insulating layers 123 to 127 do not extend to the edge of the substrate 110 due to the first crack dam CRD1, it may be possible to prevent or reduce instances of cracks caused by external impact spreading from the edge of the substrate 110 to the display area DA.

According to some embodiments, the encapsulation layer 140 may include the first encapsulation layer 141 covering the element layer 130, the second encapsulation layer 142 located on the first encapsulation layer 141 and made of an organic insulating material, and the third encapsulation layer 143 covering the second encapsulation layer 142. Each of the first encapsulation layer 141 and the third encapsulation layer 143 may include an inorganic insulating material.

The second encapsulation layer 142 may include an organic insulating material such as acryl resin, epoxy resin, phenolic resin, polyamide resin, polyimide resin and the like.

The second encapsulation layer 142 may be prepared by a process in which an organic insulating material in a liquid state is dropped onto the first encapsulation layer 141, is spread to cover the display area DA, and then is cured.

The range where the organic insulating material of the second encapsulation layer 142 is spread may be limited by the one or more dam portions DM1 and DM2 of the dam area DMA.

That is, the second encapsulation layer 142 may be located in the area surrounded by the one or more dam portions DM1 and DM2.

Accordingly, in the junction area JNA, the first encapsulation layer 141 may be in contact with the two or more inorganic insulating layers 123 to 127 of the circuit layer 120, and the third encapsulation layer 143 may be in contact with the first encapsulation layer 141.

The touch sensor layer 150 may include the touch buffer layer 151 located on the third encapsulation layer 143, the touch interlayer insulating layer 152 located on the touch buffer layer 151, and the touch planarization layer 153 located on the touch interlayer insulating layer 152.

The touch planarization layer 153 may include an organic insulating material and may be located in the display area DA. The touch planarization layer 153 may extend to a part of the non-display area NDA, but is spaced apart from the dam area DMA.

According to some embodiments, the first encapsulation layer 141 may extend to the edge of the substrate 110.

Further, the inorganic insulating layers located on the first encapsulation layer 141, that is, the third encapsulation layer 143, the touch buffer layer 151, and the touch interlayer insulating layer 152, may extend to a third boundary area BNDA3 which is the remaining area excluding the second boundary area BNDA2 in contact with the edge of the substrate 110 in the junction area JNA.

The third boundary area BNDA3, which is the area between the dam area DMA and the second boundary area BNDA2, may include the first boundary area BNDA1.

That is, the third encapsulation layer 143, the touch buffer layer 151, and the touch interlayer insulating layer 152 may extend only to the third boundary area BNDA3 of the junction area JNA.

Accordingly, at the edge of the third boundary area BNDA3, the side surface of at least one of the third encapsulation layer 143, the touch buffer layer 151, or the touch interlayer insulating layer 152 is exposed, so that a second crack dam CRD2 may be provided by the side surfaces of the third encapsulation layer 143, the touch buffer layer 151, and the touch interlayer insulating layer 152.

In other words, the second crack dam CRD2 may be the operationped portion caused by the side surfaces of the third encapsulation layer 143, the touch buffer layer 151, and the touch interlayer insulating layer 152 that are located on the first encapsulation layer 141.

Since the third encapsulation layer 143, the touch buffer layer 151, and the touch interlayer insulating layer 152 do not extend to the edge of the substrate 110 due to the second crack dam CRD2, it may be possible to prevent or reduce instances of cracks caused by external impact spreading from the edge of the substrate 110 to the display area DA.

The display device 100 according to some embodiments further includes the groove SGR located in a part of the junction area JNA and penetrating the barrier layer 121 and the buffer layer 122.

The groove SGR may be spaced apart from the edge of the substrate 110 and the dam area DMA.

The first encapsulation layer 141 extends to the edge of the substrate 110, and thus covers the groove SGR.

Further, a part of the first encapsulation layer 141 covering the groove SGR located in the junction area JNA may replicate the operationped portion of the groove SGR, and may be formed in a groove shape.

Accordingly, the lifting defects in the junction area JNA may be prevented or reduced by the groove SGR.

That is, in a process of forming the second encapsulation layer 142, a liquid organic insulating material dropped onto the display area DA may spread widely in the area surrounded by the one or more dam portions DM1 and DM2 arranged in the dam area DMA.

However, when the liquid organic insulating material whose amount is greater than a critical amount is dropped due to a process error, the spread of the organic insulating material is not limited to the one or more dam portions DM1 and DM2, so that some of the organic insulating material may overflow to the junction area JNA.

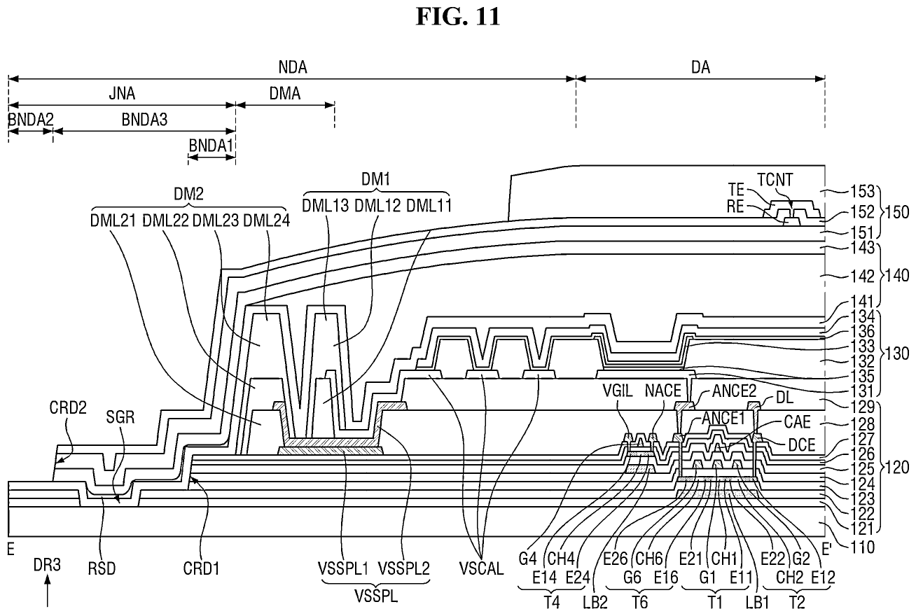

In this case, as shown in FIG. 11, according to some embodiments, when some of an organic insulating material RSD overflowing to the junction area JNA spreads to a part of the junction area JNA between the dam area DMA and the groove SGR and reaches the groove SGR, it may be accommodated on a part of the first encapsulation layer 141 formed in a groove shape while overlapping the groove SGR.

Accordingly, some of the organic insulating material overflowing to the junction area JNA is blocked by the groove SGR, thereby preventing or reducing instances of it from spreading to the edge of the substrate 110.

Therefore, the bonding between the first encapsulation layer 141 and the third encapsulation layer 143 in the junction area JNA may be reliably maintained, which may make it possible to prevent or reduce lifting defects.

Hence, the lifespan and quality reliability of the display device 100 may be improved.

As shown in FIGS. 10 and 11, according to some embodiments, the first crack dam CRD1 may be spaced apart from the groove SGR.

That is, the first crack dam CRD1 may be located adjacent to the dam area DMA compared to the groove SGR.

Accordingly, the groove SGR may be covered with the first encapsulation layer 141.

In this way, the difference between the width of the first encapsulation layer 141 overlapping the groove SGR and the width of the groove SGR may be reduced, so that the amount of an organic insulating material that may be accommodated on the first encapsulation layer 141 overlapping the groove SGR may be increased.

Further, as shown in FIGS. 10 and 11, according to some embodiments, the second crack dam CRD2 may be located between the edge of the substrate 110 and the groove SGR.

Accordingly, the third encapsulation layer 143, the touch buffer layer 151, and the touch interlayer insulating layer 152 that are located on the first encapsulation layer 141 may overlap the groove SGR.

In this way, the width of the third boundary area BNDA3, which is a junction area between the first encapsulation layer 141 and the third encapsulation layer 143 in the junction area JNA, is widened, so that the bonding between the first encapsulation layer 141 and the third encapsulation layers 143 may become relatively reliable.

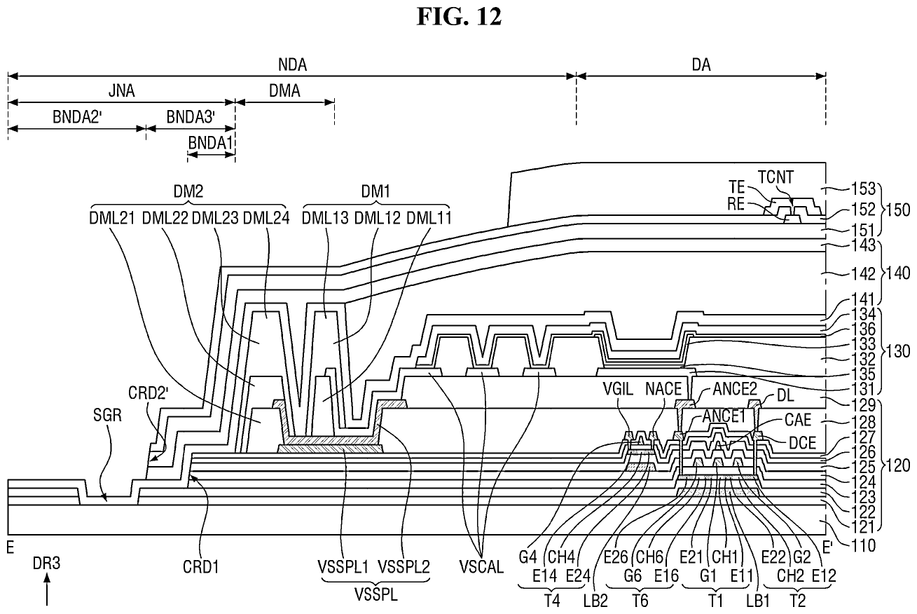

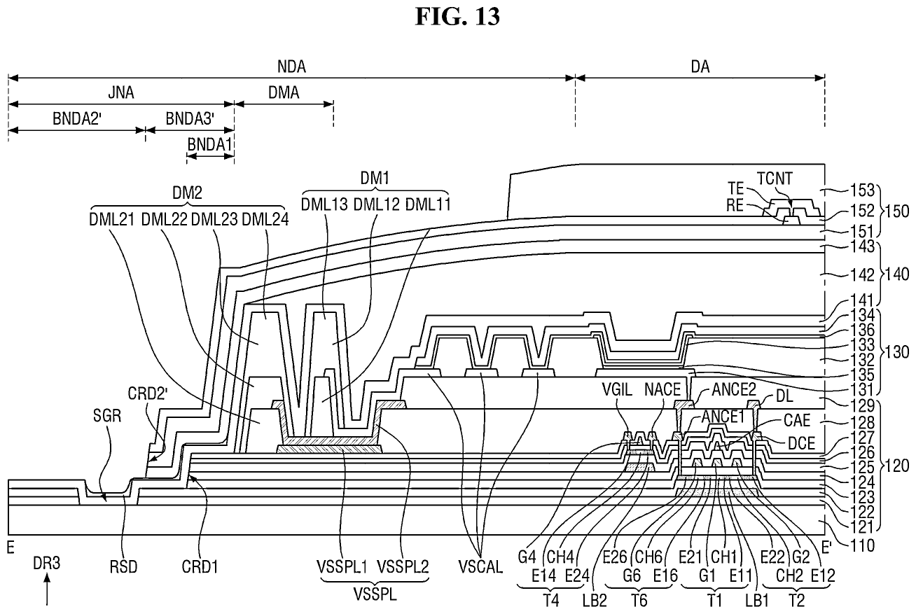

Alternatively, as shown in FIGS. 12 and 13, according to some embodiments, a second crack dam CRD2′ may be located between the groove SGR and the first crack dam CRD1.

In this case, a second boundary area BNDA2′ in contact with the edge of the substrate 110 in the junction area JNA may be wide enough to include the groove SGR.

Further, a third boundary area BNDA3′, which is the remaining area excluding the second boundary area BNDA2′ in the junction area JNA, may include the first boundary area BNDA1 corresponding to the first crack dam CRD1.

In this way, when the second crack dam CRD2′ is located between the groove SGR and the first crack dam CRD1, the third encapsulation layer 143, the touch buffer layer 151, and the touch interlayer insulating layer 152 that are located on the first encapsulation layer 141 may not overlap the groove SGR.

Accordingly, as shown in FIG. 13, some of the organic insulating material RSD accommodated on a part of the first encapsulation layer 141 overlapping the groove SGR is exposed without being covered with the third encapsulation layer 143, the touch buffer layer 151, and the touch interlayer insulating layer 152, and thus may be removed more easily.

Next, a method for manufacturing the display device 100 according to some embodiments will be described.

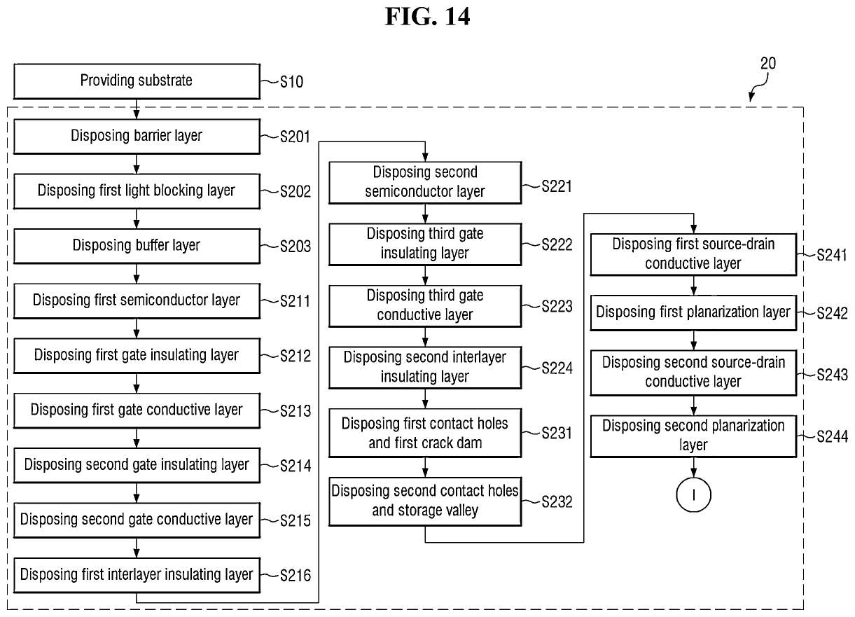

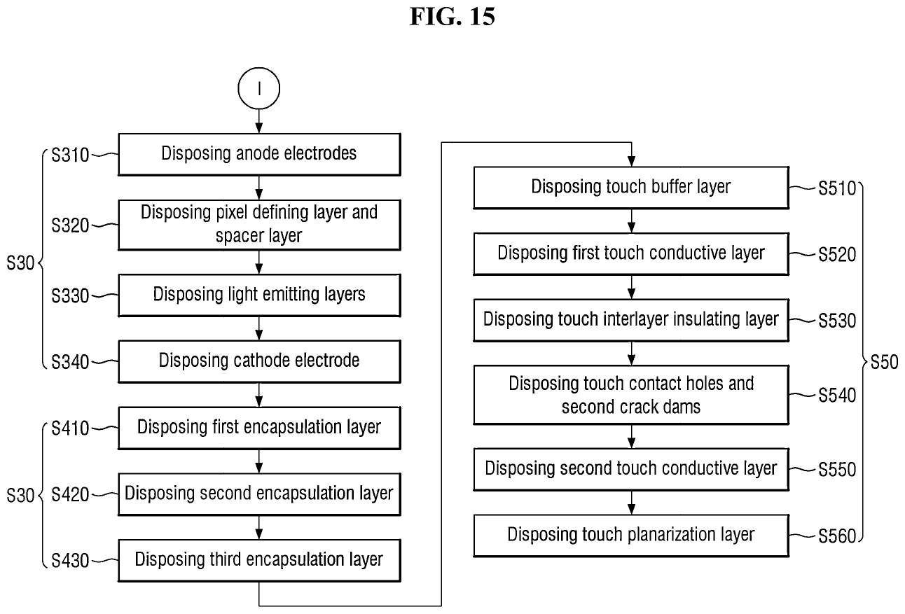

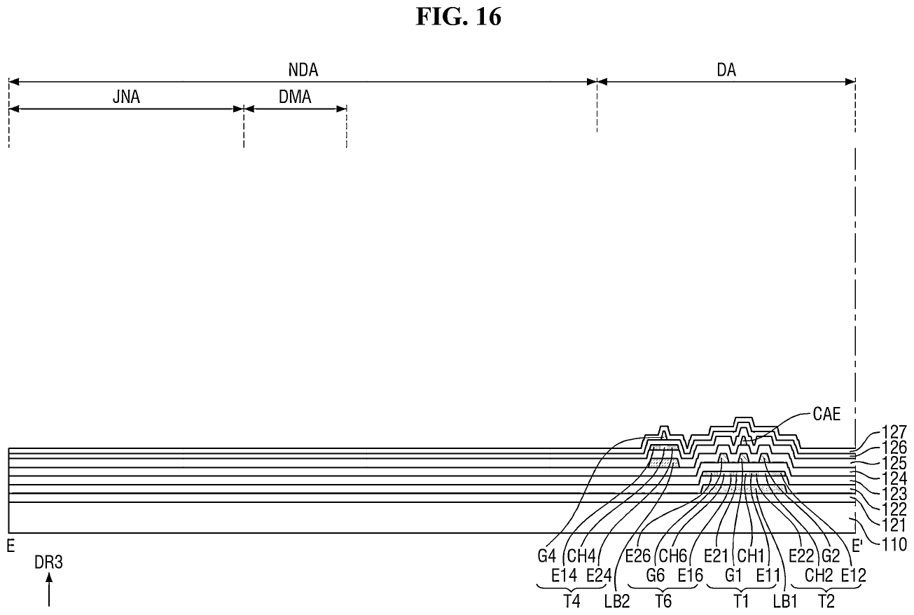

FIGS. 14 and 15 are a flowchart illustrating a method for manufacturing the display device according to some embodiments. FIGS. 16 to 28 are process views illustrating the manufacturing method of FIGS. 14 and 15 according to some embodiments.

Referring to FIG. 14, the manufacturing method of the display device 100 according to some embodiments may include providing the substrate 110 (operation S10), and forming the circuit layer 120 on the substrate 110 (operation S20).

In the operation of providing the substrate 110 (operation S10), the substrate 110 may include the main region MA including the display area DA where the emission areas EA are arranged, and the non-display area NDA arranged around the display area DA, and the sub-region SBA protruding from one side of the main region MA.

The non-display area NDA may include the dam area DMA surrounding the display area DA and spaced apart from the display area DA, and the junction area JNA located between the edge of the substrate 110 and the dam area DMA.

The junction area JNA may include the first boundary area BNDA1 in contact with the dam area DMA, and the second boundary areas BNDA2 and BNDA2′ in contact with the edge of the substrate 110.

The operation S20 of forming the circuit layer 120 may include forming the barrier layer 121 by stacking an inorganic insulating material on the substrate 110 (operation S201), forming the buffer layer 122 by stacking an inorganic insulating material on the barrier layer 121 (operation S203), and forming the groove SGR by partially removing the barrier layer 121 and the buffer layer 122 (operation S232).

According to some embodiments, the operation S20 of forming the circuit layer 120 may further include forming the first light blocking layer LB1 (operation S202) before forming the buffer layer 122 (operation S203).

According to some embodiments, the operation S20 of forming the circuit layer 120 may further include, before the operation S232 of forming the groove SGR, forming the first semiconductor layer on the buffer layer 122 (operation S211), forming the first gate insulating layer 123 covering the first semiconductor layer by stacking an inorganic insulating material on the buffer layer 122 (operation S212), forming the first gate conductive layer on the first gate insulating layer 123 (operation S213), forming the second gate insulating layer 124 covering the first gate conductive layer by stacking an inorganic insulating material on the first gate insulating layer 123 (operation S214), forming the second gate conductive layer on the second gate insulating layer 124 (operation S215), forming the first interlayer insulating layer 125 covering the second gate conductive layer by stacking an inorganic insulating material on the second gate insulating layer 124 (operation S216), forming the second semiconductor layer on the first interlayer insulating layer 125 (operation S221), forming the third gate insulating layer 126 covering the second semiconductor layer by stacking an inorganic insulating material on the first interlayer insulating layer 125 (operation S222), forming the third gate conductive layer on the third gate insulating layer 126 (operation S223), forming the second interlayer insulating layer 127 covering the third gate conductive layer by stacking an inorganic insulating material on the third gate insulating layer 126 (operation S224), and forming the first crack dam CRD1 by partially removing the second interlayer insulating layer 127, the third gate insulating layer 126, the first interlayer insulating layer 125, the second gate insulating layer 124, and the first gate insulating layer 123 (operation S231).

In the operation S231 of forming the first crack dam CRD1, the first contact holes CT1 extending from the second interlayer insulating layer 127 to one of the first semiconductor layer, the first gate conductive layer, and the second gate conductive layer may be arranged together with the first crack dam CRD1.

In the operation S232 of forming the groove SGR, the second contact holes CT2 extending from the second interlayer insulating layer 127 to one of the second semiconductor layer and the third gate conductive layer may be arranged together with the groove SGR.

According to some embodiments, the operation S20 of forming the circuit layer 120 may further include, after the operation S232 of forming the groove SGR, forming the first source-drain conductive layer on the second interlayer insulating layer 127 (operation S241), forming the first planarization layer 128 covering the first source-drain conductive layer by stacking an organic insulating material on the second interlayer insulating layer 127 (operation S242), forming the second source-drain conductive layer on the first planarization layer 128 (operation S243), and forming the second planarization layer 129 covering the second source-drain conductive layer by stacking an organic insulating material on the first planarization layer 128 (operation S244).

Referring to FIG. 15, the manufacturing method of the display device 100 according to some embodiments may further include, after the operation S20 of forming the element layer 130, forming the element layer 130 on the circuit layer 120 (operation S30), forming the encapsulation layer 140 on the element layer 130 (operation S40), and forming the touch sensor layer 150 on the encapsulation layer 140 (operation S50).

The operation S30 of forming the element layer 130 may include forming the anode electrodes 131 in the emission areas EA (operation S310), forming the pixel defining layer 132 covering the edges of the anode electrodes 131 in the non-emission area NEA between the emission areas EA and forming the spacer layer 132′ on a part of the pixel defining layer 132 (operation S320), forming the light emitting layers 133 on the anode electrodes 131 (operation S330), and forming the cathode electrode 134 on the pixel defining layer 132, the spacer layer 132′, and the light emitting layers 133 (operation S340).

The operation S40 of forming the encapsulation layer 140 may include forming the first encapsulation layer 141 containing an inorganic insulating material on the element layer 130 (operation S410), forming the second encapsulation layer 142 containing an organic insulating material on the first encapsulation layer 141 (operation S420), and forming the third encapsulation layer 143 covering the second encapsulation layer 142 and containing an inorganic insulating material on the first encapsulation layer 141 (operation S430).

The operation S50 of forming the touch sensor layer 150 may include forming the touch buffer layer 151 by stacking an inorganic insulating material on the third encapsulation layer 143 (operation S510), forming a first touch conductive layer on the touch buffer layer 151 (operation S520), forming the touch interlayer insulating layer 152 covering the first touch conductive layer by stacking an inorganic insulating material on the touch buffer layer 151 (operation S530), forming the second crack dams CRD2 and CRD2′ by partially removing the touch interlayer insulating layer 152 (operation S540), forming a second touch conductive layer on the touch interlayer insulating layer 152 (operation S550), and forming the touch planarization layer 153 covering the second touch conductive layer by stacking an organic insulating material on the touch interlayer insulating layer 152 (operation S560).

For example, in the operation S520 of forming the first touch conductive layer, the first touch conductive layer may include the bridge electrode BE.

Then, in the operation S550 of forming the second touch conductive layer, the second touch conductive layer may include the driving electrode TE and the sensing electrode RE.

In the operation S540 of forming the second crack dams CRD2 and CRD2′, the touch contact holes TCNT extending to the bridge electrode BE may be located together with the second crack dams CRD2 and CRD2′.

Referring to FIG. 16, in the operation S10 of providing the substrate 110, the substrate 110 may include the display area DA and the non-display area NDA, and the non-display area NDA may include the dam area DMA and the junction area JNA.

The display area DA may include the emission areas EA.

The dam area DMA may be spaced apart from the display area DA.

The junction area JNA may be located between the dam area DMA and the edge of the substrate 110.

In the operation S201 of forming the barrier layer 121, the barrier layer 121 entirely covering one surface of the substrate 110 may be formed by stacking an inorganic insulating material on the substrate 110.

The barrier layer 121 may extend to the edge of the substrate 110.

In the operation S202 of forming the first light blocking layer LB1, the first light blocking layer LB1 may be formed by partially removing the light blocking material on the barrier layer 121.

In the operation S203 of forming the buffer layer 122, the buffer layer 122 covering the first light blocking layer LB1 may be formed by stacking an inorganic insulating material on the barrier layer 121.

The buffer layer 122 may contain an inorganic insulating material having a composition or a component different from that of the barrier layer 121.

The buffer layer 122 may entirely overlap one surface of the substrate 110.

In the operation S211 of forming the first semiconductor layer CH1, E11, E21, CH2, E12, E22, CH6, E16, and E26, the first semiconductor layer CH1, E11, E21, CH2, E12, E22, CH6, E16, and E26 may be formed by partially removing the first semiconductor material layer on the buffer layer 122.

The first semiconductor layer may include the channel portions CH1, CH2, and CH6, the first electrode portions E11, E12, and E16, and the second electrode portions E21, E22, and E26 of the first transistor T1, the second transistor T2, the fifth transistor T5 (see FIG. 5), the sixth transistor T6, and the seventh transistor T7 that are provided as P-type MOSFETs.

The first semiconductor layer CH1, E11, E21, CH2, E12, E22, CH6, E16, and E26 may include a silicon semiconductor.

In the operation S212 of forming the first gate insulating layer 123, the first gate insulating layer 123 covering the first semiconductor layer CH1, E11, E21, CH2, E12, E22, CH6, E16, and E26 may be formed by stacking an inorganic insulating material on the buffer layer 122.

In the operation S212 of forming the first gate insulating layer 123, the first gate insulating layer 123 may extend to the edge of the substrate 110 while entirely overlapping one surface of the substrate 110.

In the operation S213 of forming the first gate conductive layer G1, G2, and G6, the first gate conductive layer G1, G2, and G6 may be formed by partially removing the conductive material layer on the first gate insulating layer 123.

The first gate conductive layer may include the gate electrodes G1, G2, and G6 of the first transistor T1, the second transistor T2, the fifth transistor T5 (FIG. 5), the sixth transistor T6, and the seventh transistor T7 that are provided as P-type MOSFETS.

In the operation S214 of forming the second gate insulating layer 124, the gate insulating layer 124 covering the first gate conductive layer G1, G2, and G6 may be formed by stacking an inorganic insulating material on the first gate insulating layer 123.

In the operation S214 of forming the second gate insulating layer 124, the first gate insulating layer 123 may extend to the edge of the substrate 110 while entirely overlapping one surface of the substrate 110.

In the operation S215 of forming the second gate conductive layer CAE and LB2, the second gate conductive layer CAE and LB2 may be formed by partially removing the conductive material layer on the second gate insulating layer 124.

The second gate conductive layer may include the capacitor electrode CAE and the second light blocking layer LB2.

In the operation S216 of forming the first interlayer insulating layer 125, the first interlayer insulating layer 125 covering the second gate conductive layer CAE and LB2 may be formed by stacking an inorganic insulating material on the second gate insulating layer 124.

In the operation S216 of forming the first interlayer insulating layer 125, the first interlayer insulating layer 125 may extend to the edge of the substrate 110 while entirely overlapping one surface of the substrate 110.

In the operation S221 of forming the second semiconductor layer CH4, E14, and E24, the second semiconductor layer CH4, E14, and E24 may be formed by partially removing the second semiconductor material layer on the first interlayer insulating layer 125.

The second semiconductor layer may include the channel portion CH4, the first electrode portion E14, and the second electrode portion E24 of the third transistor T3 (see FIG. 5) and the fourth transistor T4 that are provided as N-type MOSFETs.

The second semiconductor layer CH4, E14, and E24 may include an oxide semiconductor.

In the operation S222 of forming the third gate insulating layer 126, the third gate insulating layer 126 covering the second semiconductor layer CH4, E14, and E24 may be formed by stacking an inorganic insulating material on the first interlayer insulating layer 125.

In the operation S222 of forming the third gate insulating layer 126, the third gate insulating layer 126 may extend to the edge of the substrate 110 while entirely overlapping one surface of the substrate 110.

In the operation S223 of forming the third gate conductive layer G4, the third gate conductive layer G4 may be formed by partially removing the conductive material layer on the third gate insulating layer 126.

The third gate conductive layer may include the gate electrode G4 of the fourth transistor T4 and the third transistor T3 (see FIG. 5) that are provided as N-type MOSFETS.

In the operation S224 of forming the second interlayer insulating layer 127, the second interlayer insulating layer 127 covering the third gate conductive layer G4 may be formed by stacking an inorganic insulating material on the third gate insulating layer 126.

In the operation S224 of forming the second interlayer insulating layer 127, the second interlayer insulating layer 127 may extend to the edge of the substrate 110 while entirely overlapping one surface of the substrate 110.

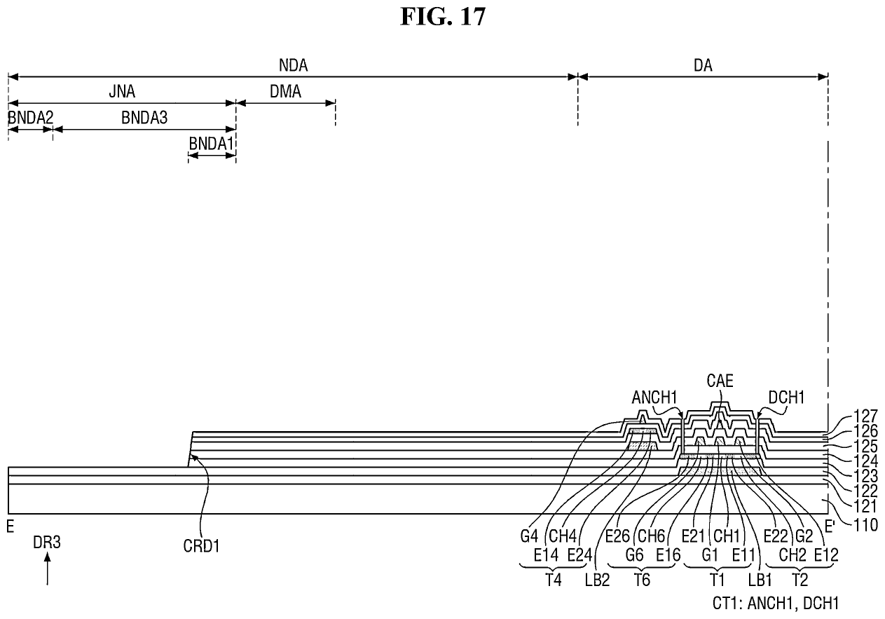

Referring to FIG. 17, in the operation S231 of forming the first crack dam CRD1, the first crack dam CRD1 and the first contact holes CT1 may be formed by partially removing the second interlayer insulating layer 127, the third gate insulating layer 126, the first interlayer insulating layer 125, the second gate insulating layer 124, and the first gate insulating layer 123.

The first contact hole CT1 may extend from the second interlayer insulating layer 127 to one of the first semiconductor layer, the first gate conductive layer, and the second gate conductive layer.

The first contact hole CT1 may include the first data connection hole DCH1 and the first anode connection hole ANCH1.

The first data connection hole DCH1 may penetrate the second interlayer insulating layer 127, the third gate insulating layer 126, the first interlayer insulating layer 125, the second gate insulating layer 124, and the first gate insulating layer 123, and may reach the first electrode portion E12 of the second transistor T2.

The first anode connection hole ANCH1 may penetrate the second interlayer insulating layer 127, the third gate insulating layer 126, the first interlayer insulating layer 125, the second gate insulating layer 124, and the first gate insulating layer 123, and may reach the second electrode portion E26 of the sixth transistor T6. The first crack dam CRD1 may include the side surfaces of the first gate

insulating layer 123, the second gate insulating layer 124, the first interlayer insulating layer 125, the third gate insulating layer 126, and the second interlayer insulating layer 127 that are located on the buffer layer 122.

Due to the first crack dam CRD1, the first gate insulating layer 123, the second gate insulating layer 124, the first interlayer insulating layer 125, the third gate insulating layer 126, and the second interlayer insulating layer 127 that are located on the buffer layer 122 may extend to the first boundary area BNDA1 in contact with the dam area DMA in the junction area JNA.

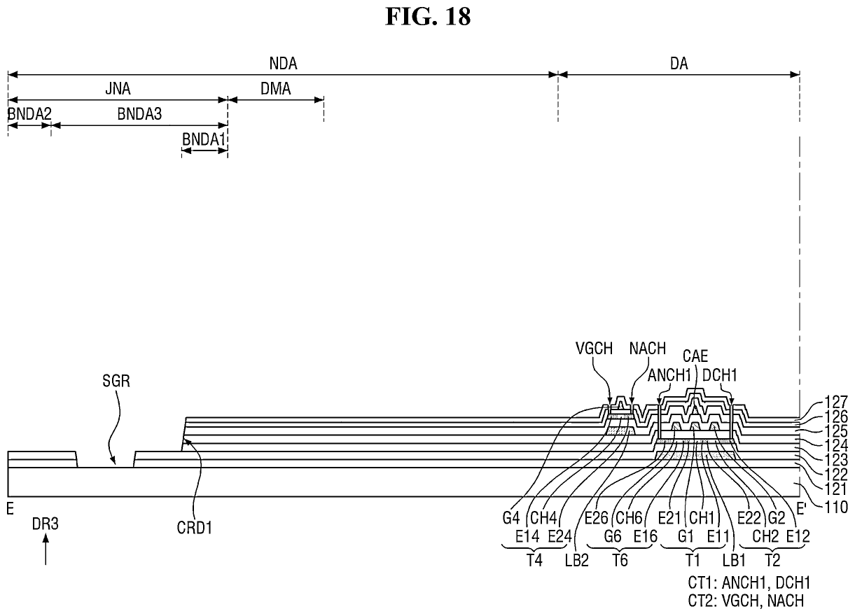

Referring to FIG. 18, in the operation S232 of forming the groove SGR, the groove SGR may be formed by partially removing the buffer layer 122 and the barrier layer 121.

The groove SGR may be located in a part of the junction area JNA and spaced apart from the dam area DMA and the edge of the substrate 110, and may penetrate the buffer layer 122 and the barrier layer 121.

In the operation S232 of forming the groove SGR, a part of the junction area JNA of the substrate 110 may be exposed by the groove SGR.

Then, in the operation S232 of forming the groove SGR, the second contact holes CT2 may be formed by partially removing the second interlayer insulating layer 127 and the third gate insulating layer 126 together with the buffer layer 122 and the barrier layer 121.

The second contact holes CT2 may extend from the second interlayer insulating layer 127 to one of the second semiconductor layer and the third gate conductive layer.

The second contact holes CT2 may include the gate initialization voltage connection hole VGCH and the node auxiliary connection hole NACH.

The gate initialization voltage connection hole VGCH may penetrate the second interlayer insulating layer 127 and the third gate insulating layer 126, and may reach the first electrode portion E14 of the fourth transistor T4.

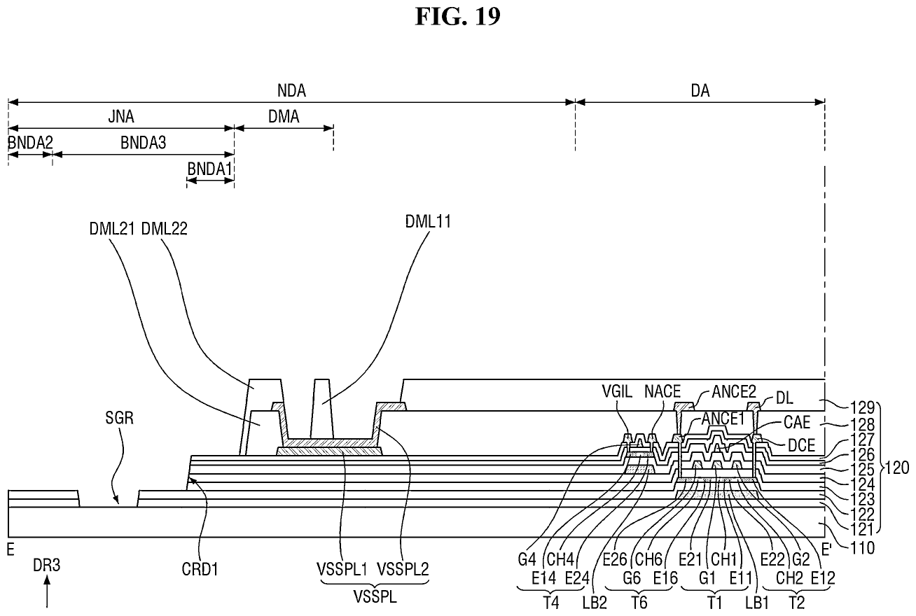

The node auxiliary connection hole NACH may penetrate the second interlayer insulating layer 127 and the third gate insulating layer 126, and may reach the second electrode portion E24 of the fourth transistor T4. Referring to FIG. 19, in the operation S241 of forming the first source-drain

conductive layer ANCE1, DCE, VGIL, and NACE, the first source-drain conductive layer ANCE1, DCE, VGIL, and NACE may be formed by partially removing the conductive material layer on the second interlayer insulating layer 127.

The first source-drain conductive layer may include the first anode connection electrode ANCE1, the data connection electrode DCE, the gate initialization voltage line VGIL, and the node auxiliary connection electrode NACE.

The first anode connection electrode ANCE1 may be electrically connected to the second electrode portion E26 of the sixth transistor T6 through the first anode connection hole ANCH1.

The data connection electrode DCE may be electrically connected to the first electrode portion E12 of the second transistor T2 through the first data connection hole DCH1.

The gate initialization voltage line VGIL may be electrically connected to the first electrode portion E14 of the fourth transistor T4 through the gate initialization voltage connection hole VGCH.

The node auxiliary connection electrode NACE may be electrically connected to the second electrode portion E24 of the fourth transistor T4 through the node auxiliary connection hole NACH.

In the operation S242 of forming the first planarization layer 128, the first planarization layer 128 covering the first source-drain conductive layer ANCE1, DCE, VGIL, and NACE may be formed by stacking an organic insulating material on the second interlayer insulating layer 127.

Further, the second data connection hole DCH2 and the second anode connection hole ANCH2 may be formed by partially removing the first planarization layer 128.

In addition, a dam layer located on the same layer as the first planarization layer 128 may be located in the dam area DMA of the non-display area NDA.

For example, the fourth dam layer DML21 of the second dam portion DM2 may be located on the same layer as the first planarization layer 128.

Next, in the operation S243 of forming the second source-drain conductive layer ANCE2 and DL, the second source-drain conductive layer ANCE2 and DL may be formed by partially removing the conductive material layer on the first planarization layer 128.

The second source-drain conductive layer ANCE2 and DL may include the second anode connection electrode ANCE2 and the data line DL.

The second anode connection electrode ANCE2 may be electrically connected to the first anode connection electrode ANCE1 through the second anode connection hole ANCH2.

The data line DL may be electrically connected to the data connection electrode DCE through the second data connection hole DCH2.

In the operation S244 of forming the second planarization layer 129, the second planarization layer 129 covering the second source-drain conductive layer ANCE2 and DL may be formed by stacking an organic insulating material on the first planarization layer 128.

Further, the third anode connection hole ANCH3 may be formed by partially removing the second planarization layer 129.

In addition, a dam layer located on the same layer as the second planarization layer 129 may be located in the dam area DMA of the non-display area NDA.

For example, the first dam layer DML11 of the first dam portion DM1 and the fifth dam layer DML22 of the second dam portion DM2 may be located on the same layer as the second planarization layer 129.

Accordingly, the circuit layer 120 may be formed (operation S20).

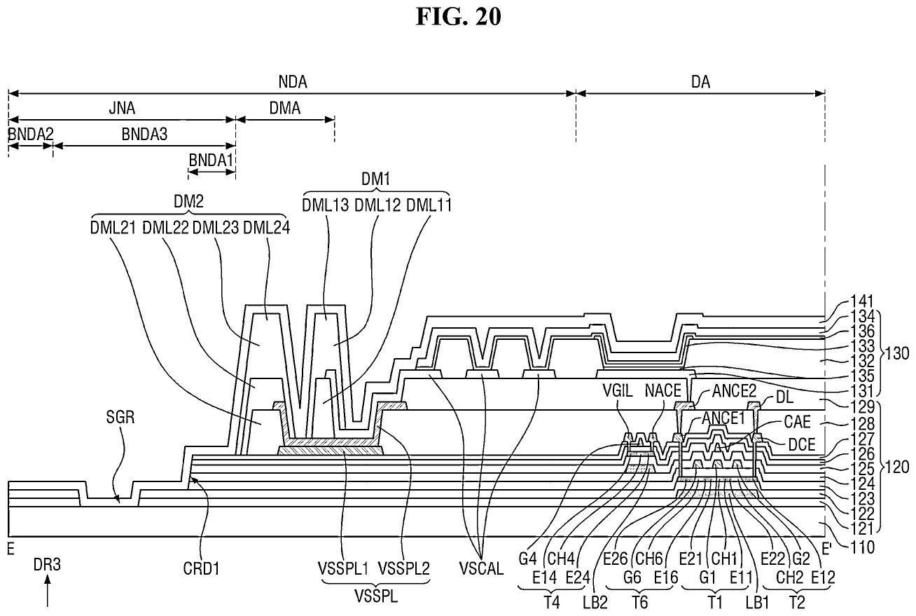

Referring to FIG. 20, in the operation S310 of forming the anode electrodes 131, the anode electrodes 131 may be located in the emission areas EA by partially removing the conductive material layer on the second planarization layer 129.

The anode electrode 131 may be electrically connected to the second anode connection electrode ANCE2 through the third anode connection hole ANCH3.

In the operation S320 of forming the pixel defining layer 132 and the spacer layer 132′, the pixel defining layer 132 located in the non-emission area NEA and the spacer layer 132′ located on a part of the pixel defining layer 132 may be provided by partially removing an organic insulating material on the second planarization layer 129 using a halftone mask.

The pixel defining layer 132 may cover the edges of the anode electrodes 131.

The pixel defining layer 132 may extend to a part of the non-display area NDA, and may be spaced apart from the dam area DMA.

In addition, dam layers located on the same layer as the pixel defining layer 132 and the spacer layer 132′ may be located in the dam area DMA of the non-display area NDA.

For example, the second dam layer DML12 of the first dam portion DM1 and the sixth dam layer DML23 of the second dam portion DM2 may be located on the same layer as the pixel defining layer 132, and the third dam layer DML13 of the first dam portion DM1 and the seventh dam layer DML24 of the second dam portion DM2 may be located on the same layer as the spacer layer 132′.

Accordingly, the one or more dam portions DM1 and DM2 may be arranged in the dam area DMA.

In the operation S330 of forming the light emitting layers 133, the first common layers 135 and the light emitting layers 133 may be located on the anode electrodes 131 by selectively depositing an organic material.

In the operation S340 of forming the cathode electrode 134, after the second common layer 136 covering the pixel defining layer 132, the spacer layer 132′, and the light emitting layers 133 is formed by entirely stacking the organic material, the cathode electrode 134 may be located on the second common layer 136 by stacking a conductive material layer.

Accordingly, the element layer 130 including the light emitting elements LE may be formed (operation S30).

Next, in the operation S410 of forming the first encapsulation layer 141, the first encapsulation layer 141 may be formed by stacking an inorganic insulating material on the cathode electrode 134.

The first encapsulation layer 141 may extend to the edge of the substrate 110 while entirely overlapping one surface of the substrate 110.

Accordingly, the first encapsulation layer 141 covers the groove SGR, and thus may include a groove corresponding to the groove SGR.

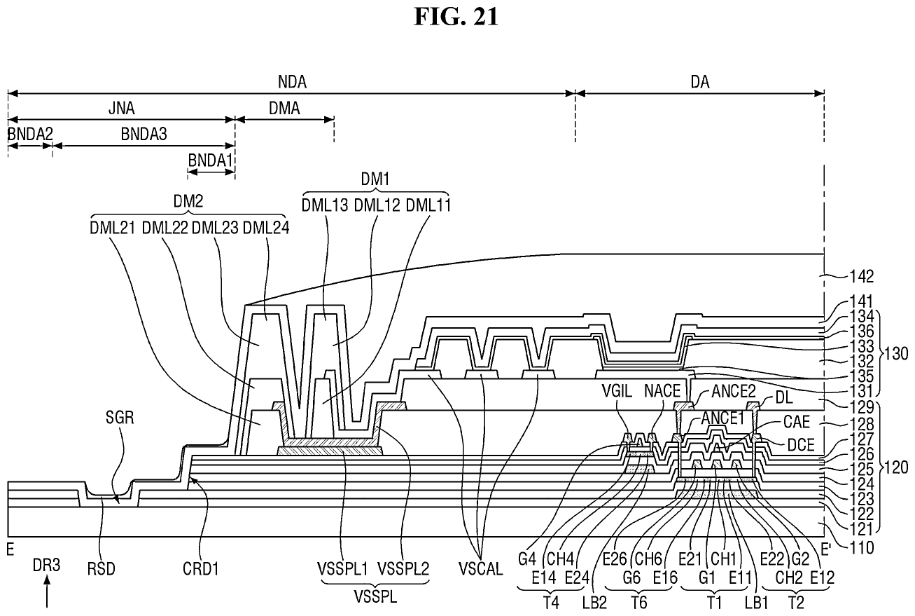

Referring to FIG. 21, in the operation S420 of forming the second encapsulation layer 142, at least one second encapsulation layer 142 may be formed by dropping a liquid organic insulating material onto the display area DA, spreading it widely, and then curing it.

In this case, the range where the liquid organic insulating material is spread may be limited to the area surrounded by one or more dam portions DM1 and DM2.

However, when the amount of the liquid organic insulating material is greater than a critical amount corresponding to the width of the area surrounded by the one or more dam portions DM1 and DM2, the liquid organic insulating material may overflow to the junction area JNA over the one or more dam portions DM1 and DM2.

In this case, some of the organic insulating material RSD overflowing to the junction area JNA may be accommodated in the groove of the first encapsulation layer 141 corresponding to the groove SGR. Accordingly, some of the organic insulating material RSD overflowing to the junction area JNA may be prevented from reaching the edge of the substrate 110.

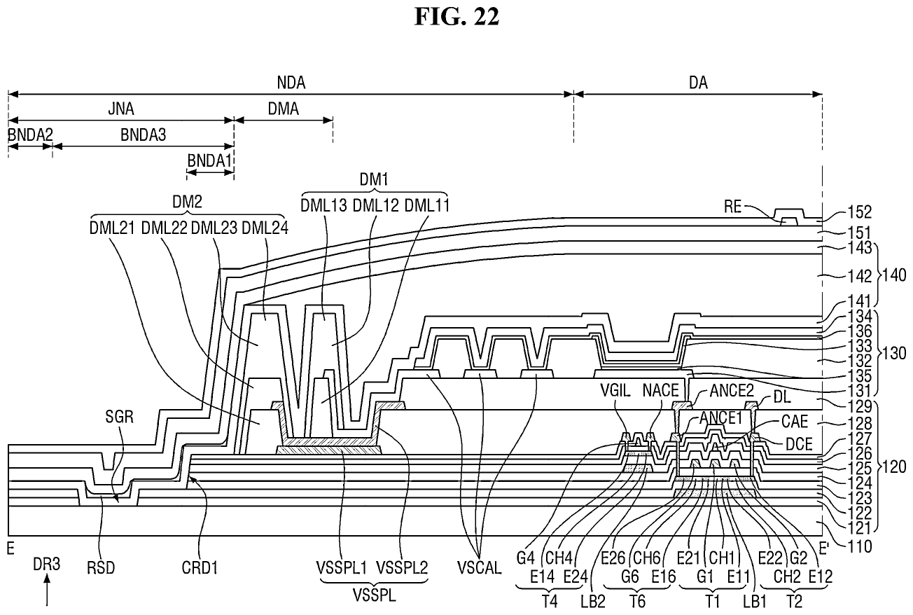

Referring to FIG. 22, in the operation S430 of forming the third encapsulation layer 143, the third encapsulation layer 143 covering the second encapsulation layer 142 may be formed by stacking an inorganic insulating material on the first encapsulation layer 141.

In the operation S430 of forming the third encapsulation layer 143, the third encapsulation layer 143 may extend to the edge of the substrate 110 while entirely overlapping one surface of the substrate 110.

Accordingly, the encapsulation layer 140 may be formed (operation S40).

In the operation S510 of forming the touch buffer layer 151, the touch buffer layer 151 may be formed by stacking an inorganic insulating material on the third encapsulation layer 143.

In the operation S510 of forming the touch buffer layer 151, the touch buffer layer 151 may extend to the edge of the substrate 110 while entirely overlapping one surface of the substrate 110.

In the operation S520 of forming the first touch conductive layer, the first touch conductive layer including the bridge electrode BE may be formed by partially removing the conductive material layer on the touch buffer layer 151.

In the operation S520 of forming the touch interlayer insulating layer 152, the touch interlayer insulating layer 152 covering the bridge electrode BE may be formed by stacking an inorganic insulating material on the touch buffer layer 151.

In the operation S520 of forming the touch interlayer insulating layer 152, the touch interlayer insulating layer 152 may extend to the edge of the substrate 110 while entirely overlapping one surface of the substrate 110.

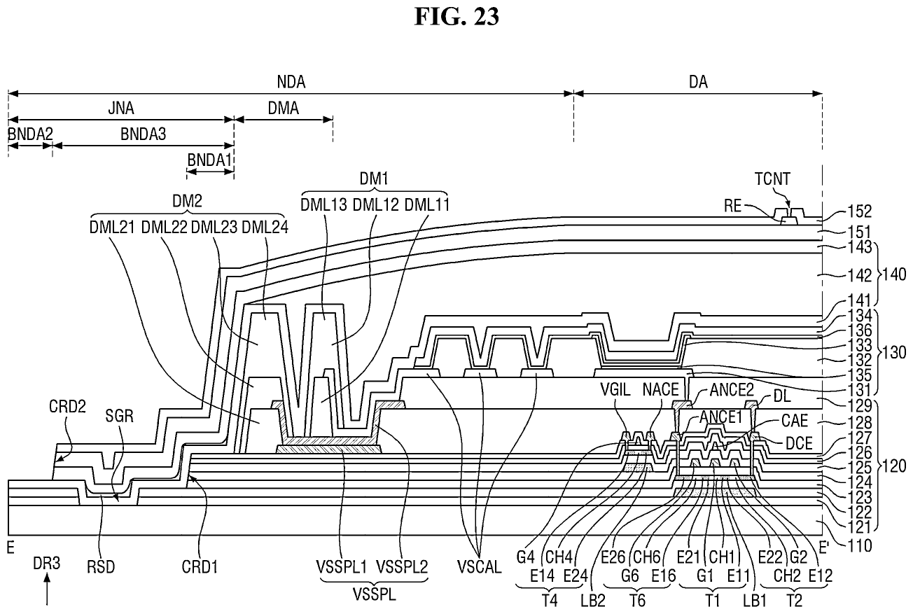

Referring to FIG. 23, in the operation S540 of forming the second crack dam CRD2, the second crack dam CRD2 and the touch contact holes TCNT may be formed by partially removing the third encapsulation layer 143, the touch buffer layer 151, and the touch interlayer insulating layer 152 that are located on the first encapsulation layer 141.

The touch contact holes TCNT may penetrate the touch interlayer insulating layer 152 and reach the bridge electrode BE.

The second crack dam CRD2 may include the side surfaces of the third encapsulation layer 143, the touch buffer layer 151, and the touch interlayer insulating layer 152 that are located on the first encapsulation layer 141.

Due to the second crack dam CRD2, the third encapsulation layer 143, the touch buffer layer 151, and the touch interlayer insulating layer 152 may extend to the third boundary area BNDA3 which is the remaining area excluding the second boundary area BNDA2 in contact with the edge of the substrate 110 in the junction area JNA.

According to some embodiments, the second crack dam CRD2 may be located between the edge of the substrate 110 and the groove SGR.

Meanwhile, in the operation S540 of forming the second crack dam CRD2, due to a decrease in the intensity or processing time of the etching process, the third encapsulation layer 143 or the touch buffer layer 151 may not be sufficiently exposed to an etching process. In this way, the damage to the bridge electrode BE due to over etching may be prevented or reduced.

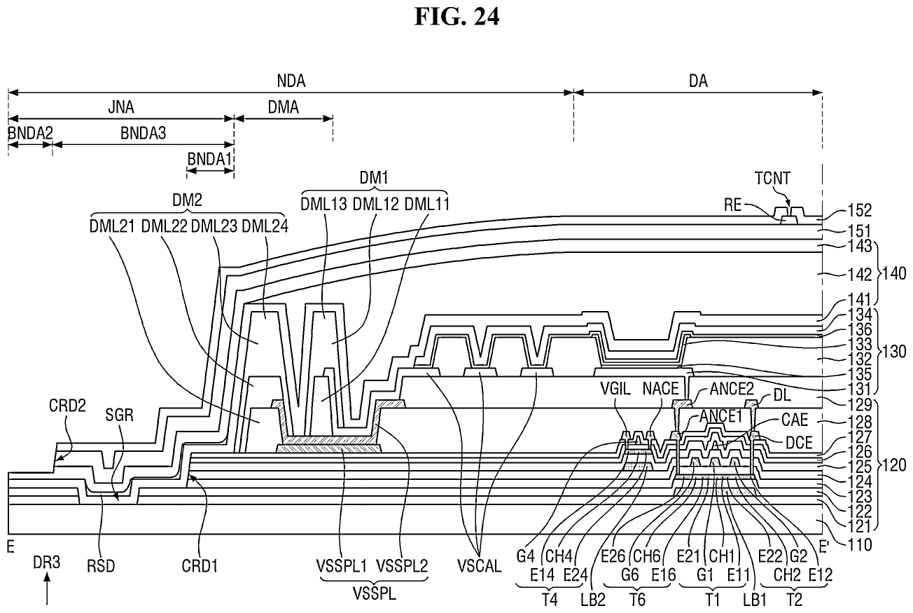

For example, as shown in FIG. 24, the second crack dam CRD2 may include a part of the side surface of the third encapsulation layer 143, and the side surfaces of the touch buffer layer 151 and the touch interlayer insulating layer 152. In this case, another part of the third encapsulation layer 143 may remain in the second boundary area BNDA2.

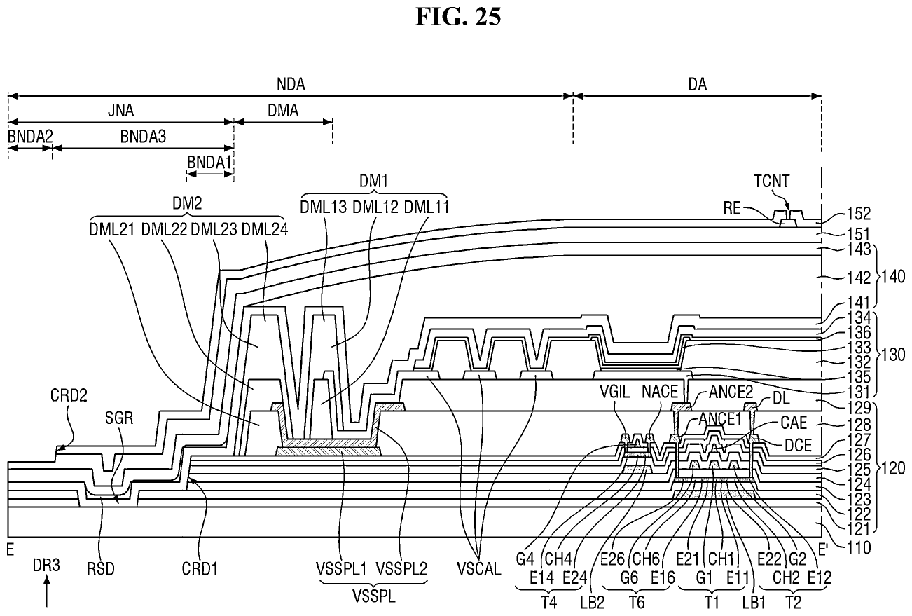

For example, as shown in FIG. 25, the second crack dam CRD2 may include a part of the side surface of the touch buffer layer 151, and the side surface of the touch interlayer insulating layer 152. In this case, another part of the touch buffer layer 151 and the third encapsulation layer 143 may remain in the second boundary area BNDA2.

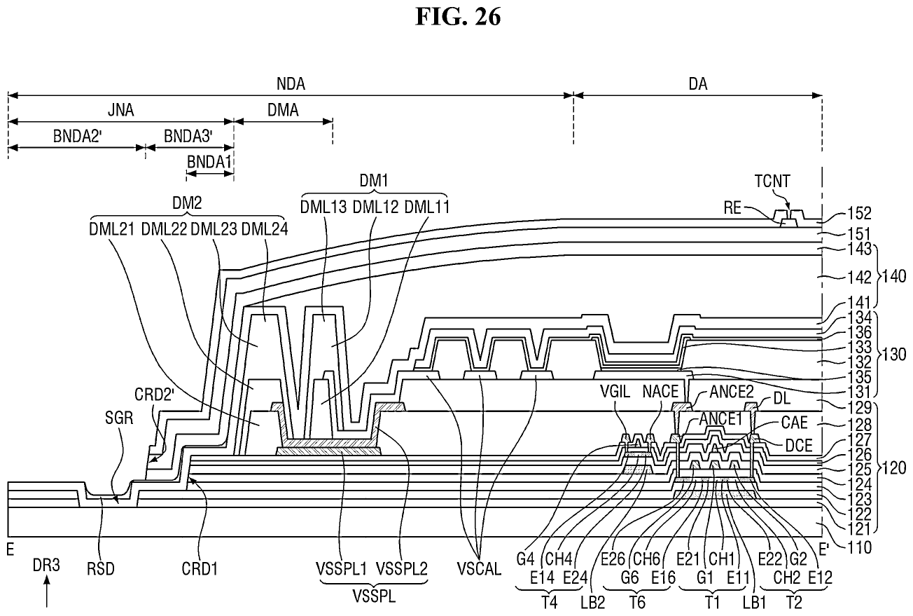

As shown in FIG. 26, according to some embodiments, the second crack dam CRD2′ may be located between the groove SGR and the first crack dam CRD1, and may include the side surfaces of the third encapsulation layer 143, the touch buffer layer 151, and the touch interlayer insulating layer 152.

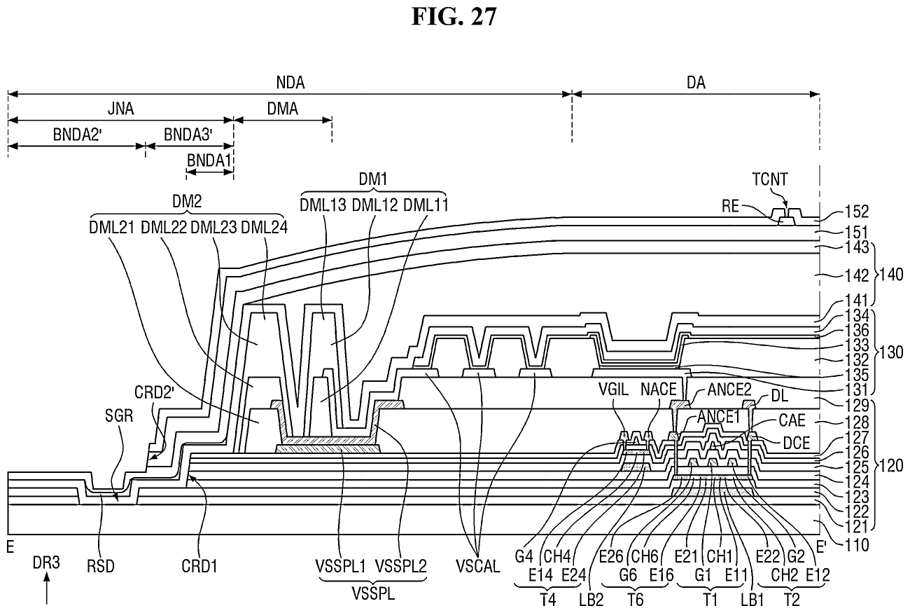

Alternatively, as shown in FIG. 27, due to a decrease in the intensity or processing time of the etching process, the second crack dam CRD2′ may include a part of the side surface of the third encapsulation layer 143, and the side surfaces of the touch buffer layer 151 and the touch interlayer insulating layer 152. In this case, another part of the third encapsulation layer 143 may remain in the second boundary area BNDA2′.

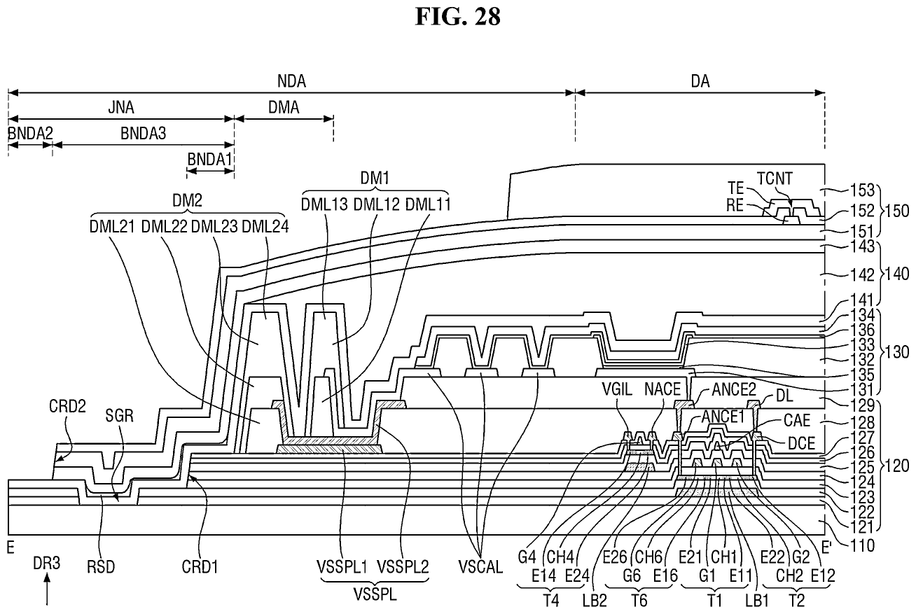

Referring to FIG. 28, in the operation S550 of forming the second touch conductive layer, the second touch conductive layer including the driving electrode TE and the sensing electrode RE may be formed by partially removing the conductive material layer on the touch interlayer insulating layer 152.

The driving electrode TE may be electrically connected to the bridge electrode BE through the touch contact hole TCNT.

In the operation S560 of forming the touch planarization layer 153, the touch planarization layer 153 covering the driving electrode TE and the sensing electrode RE may be formed by partially forming an organic insulating material on the touch interlayer insulating layer 152.

Accordingly, the touch sensor layer 150 may be formed (operation S50).

However, the effects of the present disclosure are not restricted to the one set forth herein. The above and other effects of the present disclosure will become more apparent to one of daily skill in the art to which the present disclosure pertains by referencing the appended claims, and their equivalents.

What is claimed is:

1. A display device comprising:
a substrate comprising a display area in which emission areas are arranged and a non-display area around the display area;
a circuit layer on the substrate; and
an element layer on the circuit layer,
wherein the non-display area comprises:
a dam area where at least one dam portion surrounding the display area is arranged and spaced apart from the display area; and
a junction area between an edge of the substrate and the dam area,
wherein the circuit layer comprises:
a barrier layer on the substrate;
a buffer layer on the barrier layer; and
two or more inorganic insulating layers on the buffer layer and containing an inorganic insulating material,
the display device further comprising a groove in a part of the junction area, spaced apart from the dam area and the edge of the substrate, and penetrating the barrier layer and the buffer layer.

2. The display device of claim 1, wherein the two or more inorganic insulating layers extend to a first boundary area in contact with the dam area in the junction area,
a first crack dam is provided by side surfaces of the two or more inorganic insulating layers, and
the first crack dam is spaced apart from the groove.

3. The display device of claim 2, further comprising:
an encapsulation layer on the element layer; and
a touch sensor layer on the encapsulation layer,
wherein the encapsulation layer comprises:
a first encapsulation layer on the element layer and containing an inorganic insulating material;
a second encapsulation layer in the display area on the first encapsulation layer and containing an organic insulating material; and
a third encapsulation layer on the first encapsulation layer, covering the second encapsulation layer, and containing an inorganic insulating material,
wherein the touch sensor layer comprises:
a touch buffer layer on the third encapsulation layer and containing an inorganic insulating material; and
a touch interlayer insulating layer on the touch buffer layer and containing an inorganic insulating material,
wherein the first encapsulation layer extends to the edge of the substrate, and covers the at least one dam portion and the groove,
the second encapsulation layer is in an area surrounded by the at least one dam portion,
the touch interlayer insulating layer extends to a third boundary area which is the remaining area excluding a second boundary area in contact with the edge of the substrate in the junction area, and
a second crack dam comprising a side surface of the touch interlayer insulating layer is provided.

4. The display device of claim 3, wherein the second crack dam is between the edge of the substrate and the groove, and
the touch interlayer insulating layer overlaps the groove.

5. The display device of claim 3, wherein the second crack dam is between the groove and the first crack dam.

6. The display device of claim 3, wherein at least a part of the touch buffer layer or at least a part of the third encapsulation layer extends to the third boundary area, and
the second crack dam further comprises a side surface of the touch buffer layer or a side surface of the third encapsulation layer.

7. The display device of claim 3, wherein some of the organic insulating material of the second encapsulation layer which overflows to the junction area spreads to a part of the junction area between the dam area and the groove, and is accommodated on a part of the first encapsulation layer which overlaps the groove.

8. The display device of claim 3, wherein the substrate comprises a main region comprising the display area and the non-display area, and a sub-region protruding from one side of the main region, and
the groove faces the other sides except one side connected to the sub-region in the edge of the main region.

9. The display device of claim 3, wherein the two or more inorganic insulating layers comprise:
a first gate insulating layer covering a first semiconductor layer on the buffer layer;
a second gate insulating layer covering a first gate conductive layer on the first gate insulating layer;
a first interlayer insulating layer covering a second gate conductive layer on the second gate insulating layer;
a third gate insulating layer covering a second semiconductor layer on the first interlayer insulating layer; and
a second interlayer insulating layer covering a third gate conductive layer on the third gate insulating layer.

10. The display device of claim 9, wherein the circuit layer further comprises one or more planarization layers on the second interlayer insulating layer and containing an organic insulating material,
the element layer comprises:
anode electrodes respectively in the emission areas;
a pixel defining layer in a non-emission area between the emission areas, and covering an edge of each of the anode electrodes;
a spacer layer on a part of the pixel defining layer;
light emitting layers respectively on the anode electrodes; and
a cathode electrode on the pixel defining layer, the spacer layer, and the light emitting layers,
wherein each of the at least one dam portion comprises two or more dam layers which are sequentially stacked, and
each of the two or more dam layers is the same layer as one of the one or more planarization layers, the pixel defining layer, and the spacer layer.

11. A method for manufacturing a display device, comprising:
providing a substrate comprising a display area in which emission areas are arranged and a non-display area around the display area; and
forming a circuit layer on the substrate,
wherein the non-display area comprises:
a dam area spaced apart from the display area and surrounding the display area; and
a junction area between an edge of the substrate and the dam area,
wherein forming the circuit layer comprises:
forming a barrier layer by stacking an inorganic insulating material on the substrate;
forming a buffer layer by stacking an inorganic insulating material on the barrier layer; and
forming a groove by partially removing the barrier layer and the buffer layer,
wherein the groove is in a part of the junction area, and is spaced apart from the dam area and the edge of the substrate.

12. The method of claim 11, wherein the junction area further comprises a first boundary area in contact with the dam area, and a second boundary area in contact with the edge of the substrate,
wherein forming the circuit layer further comprises:
before the forming of the groove, forming a first semiconductor layer on the buffer layer;
forming a first gate insulating layer covering the first semiconductor layer by stacking an inorganic insulating material on the buffer layer;
forming a first gate conductive layer on the first gate insulating layer;
forming a second gate insulating layer covering the first gate conductive layer by stacking an inorganic insulating material on the first gate insulating layer;
forming a second gate conductive layer on the second gate insulating layer;
forming a first interlayer insulating layer covering the second gate conductive layer by stacking an inorganic insulating material on the second gate insulating layer;
forming a second semiconductor layer on the first interlayer insulating layer;
forming a third gate insulating layer covering the second semiconductor layer by stacking an inorganic insulating material on the first interlayer insulating layer;
forming a third gate conductive layer on the third gate insulating layer;
forming a second interlayer insulating layer covering the third gate conductive layer by stacking an inorganic insulating material on the third gate insulating layer; and
forming a first crack dam comprising side surfaces of the second interlayer insulating layer, the third gate insulating layer, the first interlayer insulating layer, the second gate insulating layer, and the first gate insulating layer by partially removing the second interlayer insulating layer, the third gate insulating layer, the first interlayer insulating layer, the second gate insulating layer, and the first gate insulating layer,
wherein after the forming of the first crack dam, the second interlayer insulating layer, the third gate insulating layer, the first interlayer insulating layer, the second gate insulating layer, and the first gate insulating layer extend to the first boundary area, and
the first crack dam is spaced apart from the groove.

13. The method of claim 12, further comprising:
after forming the circuit layer, forming an element layer on the circuit layer;
forming an encapsulation layer on the element layer; and
forming a touch sensor layer on the encapsulation layer,
wherein forming the encapsulation layer comprises:
forming a first encapsulation layer containing an inorganic insulating material on the element layer;
forming a second encapsulation layer containing an organic insulating material on the first encapsulation layer; and
forming, on the first encapsulation layer, a third encapsulation layer covering the second encapsulation layer and containing an inorganic insulating material,
wherein forming the touch sensor layer comprises:
forming a touch buffer layer by stacking an inorganic insulating material on the third encapsulation layer;
forming a first touch conductive layer on the touch buffer layer;
forming a touch interlayer insulating layer covering the first touch conductive layer by stacking an inorganic insulating material on the touch buffer layer;
forming a second crack dam comprising a side surface of the touch interlayer insulating layer by partially removing the touch interlayer insulating layer;
forming a second touch conductive layer on the touch interlayer insulating layer; and
forming a touch planarization layer covering the second touch conductive layer by stacking an organic insulating material on the touch interlayer insulating layer,
wherein after forming the second crack dam, the touch interlayer insulating layer extends to a third boundary area which is the remaining area excluding the second boundary area in the junction area.

14. The method of claim 13, wherein the second crack dam is between the edge of the substrate and the groove, and
the touch interlayer insulating layer overlaps the groove.

15. The method of claim 13, wherein the second crack dam is between the groove and the first crack dam.

16. The method of claim 13, wherein in forming the second crack dam, the touch buffer layer or the third encapsulation layer is partially removed,
at least a part of the touch buffer layer or at least a part of the third encapsulation layer extends to the third boundary area, and
the second crack dam further comprises a side surface of the touch buffer layer or a side surface of the third encapsulation layer.

17. The method of claim 13, wherein after forming the element layer, at least one dam portion surrounding the display area is in the dam area,
forming the second encapsulation layer comprises a process of dropping a liquid organic insulating material on the first encapsulation layer, a process of spreading the organic insulating material into an area surrounded by the at least one dam portion, and a process of curing the organic insulating material, and
in the process of spreading the organic insulating material, some of the organic insulating material overflowing into the junction area spreads into a part of the junction area between the dam area and the groove, and is accommodated on a part of the first encapsulation layer which overlaps the groove.

18. The method of claim 13, wherein in forming the substrate, the substrate comprises a main region comprising the display area and the non-display area, and a sub-region protruding from one side of the main region, and
in the forming of the groove, the groove faces the other sides except one side connected to the sub-region in the edge of the main region.

19. The method of claim 13, wherein in forming the first crack dam, first contact holes are further formed,
in forming the groove, second contact holes are further formed,
each of the first contact holes reaches one of the first semiconductor layer, the first gate conductive layer, and the second gate conductive layer, and
each of the second contact holes reaches one of the second semiconductor layer and the third gate conductive layer.

20. The method of claim 19, wherein the forming of the circuit layer further comprises: after forming the groove, forming a first source-drain conductive layer on the second interlayer insulating layer;
forming a first planarization layer covering the first source-drain conductive layer by stacking an organic insulating material on the second interlayer insulating layer;
forming a second source-drain conductive layer on the first planarization layer; and
forming a second planarization layer covering the second source-drain conductive layer by stacking an organic insulating material on the first planarization layer,
wherein forming the element layer comprises:
forming anode electrodes in the emission areas;
forming a pixel defining layer covering edges of the anode electrodes in a non-emission area between the emission areas, and forming a spacer layer on a part of the pixel defining layer;
forming light emitting layers on the anode electrodes; and
forming a cathode electrode on the pixel defining layer, the spacer layer, and the light emitting layers,
wherein each of the at least one dam portion comprises two or more dam layers which are sequentially stacked, and
each of the two or more dam layers is the same layer as one of the first planarization layer, the second planarization layer, the pixel defining layer, and the spacer layer.
